(19) United States
(12) Patent Application Publication
(10) Pub. No.: US 2025/0344558 A1
(43) Pub. Date: Nov. 6, 2025

(54) OPTICALLY ACTIVE STRUCTURES AND PROCESSES FOR PREPARING AND DEVICES THEREOF

(71) Applicant: EDISON INNOVAIONS, LLC., Allen, TX (US)

(72) Inventors: Aharon Yakimov, Niskayuna, NY (US); James E. Murphy, Niskayuna, NY (US); Gurvinder Singh Khinda, Niskayuna, NY (US); Robert Macdonald, Niskayuna, NY (US)

(21) Appl. No.: 18/654,432

(22) Filed: May 3, 2024

(51) Int. Cl. H01L 33/50; C09K 11/08; H01L 27/15; H01L 33/00

(52) U.S. Cl. CPC H10H 20/8512; C09K 11/0833; H10H 20/01; H10H 20/0361; H10H 29/142

(57) ABSTRACT

Optically active devices and processes for preparing such devices are disclosed. A device in accordance with the present disclosure comprises a patterned surface, wherein the patterned surface comprises a plurality of pattern elements, and a plurality of LED light sources each optically coupled and/or radiationally connected to at least one pattern element of the plurality of pattern elements. The plurality of pattern elements comprise at least one optically active material and a photoresist material.

### BACKGROUND

The subject matter described herein relates generally to optically active structures and more particularly, for forming color conversion structures (e.g., films, layers, etc.) for lighting and display applications.

Narrow band emission phosphor materials achieve high color quality in lighting and displays based on LEDs. Next generation displays may incorporate mini-LEDs and micro-LEDs having active areas of 10,000 μm² or less that are capable of generating light visible to the human eye at very low drive currents. Mini-LEDs are LEDs with a size of about 100 μm to 0.7 mm. For micro-LEDs, the displays may be self-emissive or include miniaturized backlighting and arrayed with individual LEDs smaller than 100 μm.

New methods of applying phosphor materials onto the miniaturized μm-sized LED elements need to be developed to enable the full potential of mini-LED and micro-LED technologies. Coating and printing surfaces (e.g., films), such as ink jet printing, spin coating, slot die coating, and photolithography of phosphor materials is being developed to prepare LEDs including small size LEDs.

Ink jet printable ink has been prepared using quantum dots. Quantum dot material has nanometer particle sizes with a strong absorption coefficient. Quantum dots suffer from low quantum efficiency (QE) and poor thermal stability, which significantly limit their practical applications.

Phosphors have improved properties over quantum dot materials. Phosphors for use with small size LEDs must have a correspondingly small size. Printing and coating compositions require stable dispersions and phosphor materials with common organic solvents can create sedimentation or phase separation which is undesirable for subsequent coating and printing processes. Also, phosphor materials with small particle sizes tend to agglomerate when mixed with commonly used solvents making it unsuitable for ink compositions or formulations.

The demand for extremely small pixel size displays is being driven, in part, by the virtual reality and augmented reality markets, which is growing exponentially, as noted in the paper “Creating the Ultimate Virtual Reality Display”. (Joo et al., Science, September 2022). As the display industry moves towards miniaturization of the light sources (that is from mm-size LEDs to mini-LEDs to micro-LEDs), and to enhance resolution of small size displays (such as in mobile phone and wristwatch), so does the color conversion elements of the display. To enable the full potential of mini and micro-LED technologies, new methods of delivery of optically active materials (e.g., color conversion materials, such as phosphors) to the surface of LEDs are required. Currently, the preferred method of delivering color conversion materials with enhanced spatial resolution is ink-jet printing. However, ink jet printing has some limitations, including, but not limited to, an achievable resolution (smallest feature size) of about 40 microns, stringent requirements on ink formulation (such as narrow operational window for viscosity and surface tension), and limitations on the particle size and loading.

### BRIEF DESCRIPTION

Devices including phosphor materials are disclosed. The phosphor material may include a Mn⁴⁺ doped phosphor of formula 1 and at least one binder material or solvent, wherein the Mn⁴⁺ doped phosphor has a D50 particle size from about 0.1 microns to about 20 microns,

$${A}_{x} [ {M F}_{y} ] : {Mn}^{4 +} \qquad I$$

where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

The Mn⁴⁺ doped phosphors of formula I are complex fluoride materials, or coordination compounds, containing at least one coordination center surrounded by fluoride ions acting as ligands, and charge-compensated by counter ions as necessary. For example, in K₂SiF₆:Mn⁴⁺, the coordination center is Si and the counterion is K. The activator ion (Mn⁴⁺) also acts as a coordination center, substituting part of the centers of the host lattice, for example, Si. The host lattice (including the counter ions) may further modify the excitation and emission properties of the activator ion.

In particular embodiments, the coordination center of the phosphor, that is, M in formula I, is Si, Ge, Sn, Ti, Zr, Al, Ga, In, Sc, Y, La, Nb, Ta, Bi, Gd, or a combination thereof. More particularly, the coordination center may be Si, Ge, Ti, or a combination thereof. The counterion, or A in formula I, may be Li, Na, K, Rb, Cs, or a combination thereof, more particularly K or Na. Examples of phosphors of formula I include K₂[SiF₆]:Mn⁴⁺, K₂[TiF₆]:Mn⁴⁺, K₂[SnF₆]:Mn⁴⁺, Cs₂[TiF₆]:Mn⁴⁺, K₂[GeF₆]Mn⁴⁺, Rb₂[TiF₆]Mn⁴⁺, Cs₂[SiF₆]:Mn⁴⁺, Rb₂[SiF₆]:Mn⁴⁺, Na₂[SiF₆]:Mn⁴⁺, Na₂[TiF₆]:Mn⁴⁺, Na₂[ZrF₆]:Mn⁴⁺, K₃[ZrF₇]:Mn⁴⁺, K₃[BiF₆]K₃[YF₆]:Mn⁴⁺, K₃[LaF₆]:Mn⁴⁺, K₃[GdF₆]:Mn⁴⁺, K₃[NbF₇]:Mn⁴⁺, K₃[TaF₇]:Mn⁴⁺. In particular embodiments, the phosphor of formula I is K₂SiF₆:Mn⁴⁺ (PFS) or Na₂[SiF₆]:Mn⁴⁺ (NSF). In one embodiment, the ink composition comprises a KSF phosphor (K₂SiF₆:Mn) with small particle size and high manganese content.

In one embodiment, a device comprising a patterned surface is disclosed. The patterned surface comprises a plurality of pattern elements and a plurality of LED light sources are each optically coupled and/or radiationally connected to at least one pattern element of the plurality of pattern elements. The plurality of pattern elements comprise at least one optically active material and a photoresist material. In one embodiment, the patterned surface comprises a patterned film. At least one of the plurality of pattern elements may be sized less than or equal to 250 microns.

In another embodiment, a patterned film is disclosed. The patterned film comprises at least one optically active material and a photoresist material. The patterned film comprises a plurality of film elements sized less than or equal to 250 microns.

In yet another embodiment, a method for generating a patterned surface is disclosed. The method comprises depositing a composition onto a substrate comprising a plurality of light sources. The composition comprises at least one optically active material and a photoresist material. The method further comprises exposing at least one portion of the composition to light to create a patterned film comprising a plurality of film elements sized less than or equal to 250 microns.

In yet another embodiment, an ink composition is disclosed. The ink composition includes a phosphor material comprising a Mn⁴⁺ doped phosphor of formula 1, at least one binder material, at least one first solvent, and a least one second solvent, the Mn⁴⁺ doped phosphor has a D50 particle size from about 0.5 microns to about 15 microns,

$${A}_{x} [ {M F}_{y} ] : {Mn}^{4 +} \qquad I$$

where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7. The at least one first solvent comprises a first boiling point and a first surface tension and the at least one second solvent comprises a second boiling point and a second surface tension. The first boiling point is less than the second boiling point and the first surface tension is higher than the second surface tension.

### BRIEF DESCRIPTION OF DRAWINGS

These and other features, aspects, and advantages of the present disclosure will become better understood when the following detailed description is read with reference to the accompanying drawings in which like characters represent like parts throughout the drawings, wherein:

FIG. 1A is a schematic cross-sectional view of a device, in accordance with one embodiment of the disclosure.

FIG. 1B is a schematic cross-sectional view of a device in accordance with one embodiment of the disclosure.

FIG. 1C is a schematic cross-sectional view of a device in accordance with one embodiment of the disclosure.

FIG. 1D is a schematic cross-sectional view of a device in accordance with one embodiment of the disclosure.

FIG. 1E is a schematic cross-sectional view of a device in accordance with one embodiment of the disclosure.

FIG. 1F is a schematic cross-sectional view of a device, in accordance with one embodiment of the disclosure.

FIG. 1G is a schematic cross-sectional view of a device, in accordance with one embodiment of the disclosure.

FIG. 2 is a schematic cross-sectional view of a lighting apparatus, in accordance with one embodiment of the disclosure.

FIG. 3 is a schematic cross-sectional view of a lighting apparatus, in accordance with another embodiment of the disclosure.

FIG. 4 is a cutaway side perspective view of a lighting apparatus, in accordance with one embodiment of the disclosure.

FIG. 5A is a schematic perspective view of a surface-mounted device (SMD), in accordance with one embodiment of the disclosure.

FIG. 5B is a schematic cross-sectional view of an SMD in accordance with another embodiment of the disclosure.

FIG. 5C is a schematic cross-sectional view of a device in accordance with one embodiment of the disclosure.

FIG. 6A is a schematic cross-sectional view of a chip scale package (CSP) in accordance with one embodiment of the disclosure.

FIG. 6B is a schematic cross-sectional view of a CSP in accordance with another embodiment of the disclosure.

FIG. 7A is a schematic cross-sectional view of a matrix device in accordance with one embodiment of the disclosure.

FIG. 7B is a top planar view of the matrix device of FIG. 7A.

FIG. 8 is a graph showing the correlation of film thickness to thinner by wt % in accordance with one embodiment of the disclosure.

FIG. 9 is a schematic diagram of a photolithographic mask design in accordance with one embodiment of the disclosure.

FIG. 10 is a graph showing the profilometric characterization of features in accordance with one embodiment of the disclosure.

FIG. 11 is a three-dimensional graph showing the height of deposited sample ink on a substrate in accordance with one embodiment of the disclosure.

FIG. 12 is a graph showing the profilometric characterization of features in accordance with one embodiment of the disclosure.

FIG. 13 is a three-dimensional graph showing the height of deposited sample ink on a substrate in accordance with one embodiment of the disclosure.

FIGS. 14A-14C are UV microscopy maps of ink depositions in accordance with embodiments of the disclosure.

FIG. 15 is a graph showing the correlation of intensity to wavelength in accordance with one embodiment of the disclosure.

FIG. 16A is a photoluminescence photograph of a color conversion layer (CCL) pixel in accordance with embodiments of the disclosure.

FIG. 16B is a 3D laser confocal microscope photograph of a CCL pixel in accordance with embodiments of the disclosure.

FIG. 17A is a diagram showing an evaporation rate distribution of an ink composition comprising a phosphor material and at least one solvent deposited onto a surface via ink jet printing in accordance with embodiments of the disclosure.

FIG. 17B is a diagram showing an evaporation rate distribution of an ink composition comprising a phosphor material and at least one solvent deposited onto a surface in accordance with embodiments of the disclosure.

Unless otherwise indicated, the drawings provided herein are meant to illustrate features of embodiments of the disclosure. These features are believed to be applicable in a wide variety of systems comprising one or more embodiments of the disclosure. As such, the drawings are not meant to include all conventional features known by those of ordinary skill in the art to be required for the practice of the embodiments disclosed herein.

### DETAILED DESCRIPTION

In the following specification and the claims, reference will be made to a number of terms, which shall be defined to have the following meanings.

The singular forms “a”, “an”, and “the” include plural references unless the context clearly dictates otherwise. As used herein, the term “or” is not meant to be exclusive and refers to at least one of the referenced components being present and includes instances in which a combination of the referenced components may be present, unless the context clearly dictates otherwise.

Approximating language, as used herein throughout the specification and claims, may be applied to modify any quantitative representation that could permissibly vary without resulting in a change in the basic function to which it is related. Accordingly, a value modified by a term or terms, such as “about,” “substantially,” and “approximately,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

“Optional” or “optionally” means that the subsequently described event or circumstance may or may not occur, or that the subsequently identified material may or may not be present, and that the description includes instances where the event or circumstance occurs or where the material is present, and instances where the event or circumstance does not occur, or the material is not present.

The term “ink composition”, as used herein, should be understood to mean a solution comprising a plurality of materials. For example, an ink composition in accordance with the present disclosure may comprise one or more optically active materials (e.g., color conversion materials, such as phosphors), in combination with one or more components including at least one binder material, photoresist material, and/or solvent. In one embodiment, an ink composition is a stable solution with the narrow band emission phosphor particles suspended and uniformly dispersed throughout the liquid composition, as disclosed in U.S. Pat. No. 11,312,876, the entire contents of each of which are incorporated herein by reference. The particulate size of the phosphor and viscosity of the ink composition affect the stability of the composition. Reducing the particulate size of the phosphor material and increasing the viscosity of the liquid composition may improve the stability of the ink formulation by decreasing the sedimentation rate.

The term “film”, as used herein, should be understood to mean a layer of material. A film in accordance with the present disclosure may be prepared by depositing the material on a surface, such as a substrate. The term “layer”, as used herein, refers to a material disposed on at least a portion of an underlying surface in a continuous or discontinuous manner. The term “layer” does not necessarily mean a uniform thickness of the disposed material, and the disposed material may have a uniform or a variable thickness.

As used herein, the term “disposed on” refers to layers or materials disposed directly in contact with each other or indirectly by having intervening layers or features there between, unless otherwise specifically indicated.

The term “discrete region”, as used herein, should be understood to mean a region defined by an area formed using an optically active material, such as an ink composition comprising a phosphor with a clear boundaries. In one embodiment, a discrete region includes an area that contains a cured phosphor composition containing region. In another embodiment, a discrete region includes an area largely void of cured phosphor containing region.

The term “patterned film”, as used herein, should be understood to mean a film comprising a plurality of discrete regions. A patterned film in accordance with the present disclosure may be prepared by depositing a material, such as an ink composition, on a surface. The material may include an optically active material. A patterned film may be formed by depositing the material on a surface and then subsequently going through a curing process which may include heat and/or light.

The term “patterned film element”, as used herein, should be understood to mean one of the discrete regions of the plurality of discrete regions that contain phosphor, which make up a patterned film.

The term “patterned surface”, as used herein, should be understood to mean a surface comprising a plurality of discrete regions.

The term “sized less than or equal to ‘X’ microns”, as used herein, should be understood to mean a length, a width or a height less than or equal to ‘X’ microns. For example an element “sized less than or equal to 250 microns may be understood to mean the element has a width of 250 microns or less.

The term “a mini-LED” as used herein, should be understood to mean an LED that is sized less than or equal to 250 microns. For example, a mini-LED may comprise an LED that has a length of 250 microns and a width of 250 microns.

The term “a micro-LED”, as used herein, should be understood to mean an LED that is sized less than or equal to 50 microns. For example, a micro-LED may comprise an LED that has a length of 50 microns and a width of 50 microns.

Square brackets in the formulas indicate that at least one of the elements is present in the phosphor material, and any combination of two or more thereof may be present.

For example, the formula [Ca,Sr,Ba]₃MgSi₂O₈:Eu²⁺,Mn²⁺ encompasses at least one of Ca, Sr or Ba or any combination of two or more of Ca, Sr or Ba. Examples include Ca₃MgSi₂O₈:Eu²⁺·Mn²⁺; Sr₃MgSi₂O₈:Eu²⁺·Mn²⁺; or Ba₃MgSi₂O₈:Eu²⁺·Mn²⁺. Formula with an activator after a colon “:” indicates that the phosphor material is doped with the activator. Formula showing more than one activator separated by a “,”after a colon “:” indicates that the phosphor material is doped with either activator or both activators. For example, the formula [Ca,Sr,Ba]₃MgSi₂O₈:Eu²⁺,Mn²⁺ encompasses [Ca,Sr,Ba]₃MgSi₂O₈:Eu²⁺, [Ca,Sr,Ba]₃MgSi₂O₈:Mn²⁺ or [Ca,Sr,Ba]₃MgSi₂O₈:Eu²⁺ and Mn²⁺.

In one aspect, an ink composition is provided. The ink composition includes a binder material and at least one narrow band emission phosphor being uniformly dispersed throughout the composition. The narrow band emission phosphor has a D50 particle size from about 0.1 microns to about 20 microns and may comprise a red-emitting phosphor based on complex fluoride materials activated by Mn⁴⁺, and a mixture thereof. The ink composition may comprise any of the ink compositions described in International Application No. PCT/US2023/020966 or International Application No. PCT/US2023/02092, the entire contents of each of which are incorporated herein by reference.

The ink composition or formulation is a solution and may be used to prepare conversion structures, such as films, by coating or printing the ink composition, such as by one or more of ink jet printing, flexographic printing, micro-dispensing printing, screen printing, direct write printing, aerosol jet printing, gravure printing, slot die coating, spin coating, lithography, or the like. In some embodiments, the films may be deposited or printed on LEDs, mini-LEDs, OLEDs, or micro-LEDs. The conversion films convert light from one wavelength to another. For example, in some embodiments, the conversion films convert blue LED light to red light.

The ink composition includes phosphor material. The type, quantity, and size of phosphor is determined by the optical application specifically the color point and optical density.

The phosphor material may be present in the ink composition from about 1 wt % to about 50 wt %. In another embodiment, the phosphor material is present from about 2 wt % to about 30 wt %. In another embodiment, the phosphor material is present from about 3 wt % to about 20 wt %. In another embodiment, the phosphor material is present from about 5 wt % to about 15 wt %. The wt % for the phosphor material is relative to the total weight of the ink composition. For example, 100 grams of an ink composition that is 30 wt % of phosphor material corresponds to 30 grams of phosphor material, with the remaining 70 grams of the ink composition comprising a sum of all other components present in the ink composition.

In some embodiments, a liquid ink formulation may be prepared by combining a binder material with phosphor particles, and optionally, a liquid media. In some embodiments, a liquid varnish is formed.

As noted above, the ink composition comprises a narrow band emission phosphor. Narrow band emission phosphor materials achieve high color quality lighting and displays. Phosphors for use in the ink formulations include narrow band red-emitting phosphors having small particle sizes, which improve color conversion.

More particularly, in some embodiments, the ink composition includes a phosphor material including a Mn⁴⁺ doped phosphor of formula 1 and at least one binder material or solvent, wherein the Mn⁴⁺ doped phosphor has a D50 particle size from about 0.1 microns to about 20 microns,

$${A}_{x} [ {M F}_{y} ] : {Mn}^{4 +} \qquad I$$

where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

The Mn⁴⁺ doped phosphors of formula I are complex fluoride materials, or coordination compounds, containing at least one coordination center surrounded by fluoride ions acting as ligands, and charge-compensated by counter ions as necessary. For example, in K₂SiF₆:Mn⁴⁺, the coordination center is Si and the counterion is K. The activator ion (Mn⁴⁺) also acts as a coordination center, substituting part of the centers of the host lattice, for example, Si. The host lattice (including the counter ions) may further modify the excitation and emission properties of the activator ion.

In particular embodiments, the coordination center of the phosphor, that is, M in formula I, is Si, Ge, Sn, Ti, Zr, Al, Ga, In, Sc, Y, La, Nb, Ta, Bi, Gd, or a combination thereof. More particularly, the coordination center may be Si, Ge, Ti, or a combination thereof. The counterion, or A in formula I, may be Li, Na, K, Rb, Cs, or a combination thereof, more particularly K or Na. Examples of phosphors of formula I include K₂[SiF₆]:Mn⁴⁺, K₂[TiF₆]:Mn⁴⁺, K₂[SnF₆]:Mn⁴⁺, Cs₂[TiF₆]:Mn⁴⁺, K₂[GeF₆]Mn⁴⁺, Rb₂[TiF₆]Mn⁴⁺, Cs₂[SiF₆]:Mn⁴⁺, Rb₂[SiF₆]:Mn⁴⁺, Na₂[SiF₆]:Mn⁴⁺, Na₂[TiF₆]:Mn⁴⁺, Na₂[ZrF₆]:Mn⁴⁺, K₃[ZrF₇]:Mn⁴⁺, K₃[BiF₆]K₃[YF₆]:Mn⁴⁺, K₃[LaF₆]:Mn⁴⁺, K₃[GdF₆]:Mn⁴⁺, K₃[NbF₇]:Mn⁴⁺, K₃[TaF₇]:Mn⁴⁺. In particular embodiments, the phosphor of formula I is K₂SiF₆:Mn⁴⁺ (PFS) or Na₂[SiF₆]:Mn⁴⁺ (NSF).

The amount of activator Mn incorporation in the Mn⁴⁺ doped phosphors (referred to as Mn %) improves color conversion. Increasing the amount of Mn % incorporation improves color conversion by increasing the intensity of the red emission, maximizing absorption of excitation blue light and reducing the amount of unconverted blue light or bleed-through of blue light from a blue LED.

In one embodiment, the red-emitting Mn⁴⁺ doped phosphor has a Mn loading or Mn % of at least 1 wt %. In another embodiment, the red-emitting phosphor has a Mn loading of at least 1.5 wt %. In another embodiment, the red-emitting phosphor has a Mn loading of at least 2 wt %. In another embodiment, the red-emitting phosphor has a Mn % of at least 3 wt %. In another embodiment the Mn % is greater than 3.0 wt %. In another embodiment, the content of Mn in the red-emitting phosphor is from about 1 wt % to about 4 wt %. In another embodiment, the red-emitting phosphor has a Mn % from about 2 wt % to about 5 wt %.

In one embodiment, the ink composition comprises a KSF phosphor (K₂SiF₆:Mn) with small particle size and high manganese content. As opposed to quantum dot color filter solutions, KSF phosphor (K₂SiF₆:Mn) has a narrower emission intensity, less self-absorption issues in thick films, less decrease in quantum efficiency when cured into a color filter part, high thermal stability, and stability under high humidity. In further embodiments, the KSF phosphor has a D50 particle size from about 0.1 μm to about 15 μm and comprises a Mn content of at least 2.0 wt %. In further embodiments, the KSF phosphor has a D50 particle size from about 0.1 μm to about 8 μm and comprises a Mn content of at least 2.0 wt %. In further embodiments, the KSF phosphor has a D50 particle size from about 0.1 μm to about 4 μm and comprises a Mn content of 2.0-4.0 wt %. In other embodiments, the ink composition includes an NSF phosphor (Na₂SiF₆) with small particle size and high manganese content. The ink composition may be cured using hot air, UV light, and/or any other method known in the art.

In some embodiments, an LED light source may be coated with an ink composition comprising a KSF phosphor, as described above by lithography, ink jet printing, stencil printing, spin coating or slot die coating, or any other printing or deposition method known in the art. The ink composition may further comprise a surface agent such as MgF₂ to allow for a well dispersed KSF ink with good printability that absorbs the majority of the excitation light (e.g., blue light or UV light) and has a quantum efficiency of greater than 80%. Such ink compositions lack self-absorption, have good reliability, and do not require encapsulation. Further, typical KSF inks require 30-70% loading to absorb the majority of excitation light in a well having a depth of 8-16 μm. Such embodiments enable a functioning display when excited by blue LED or OLED light or UV light.

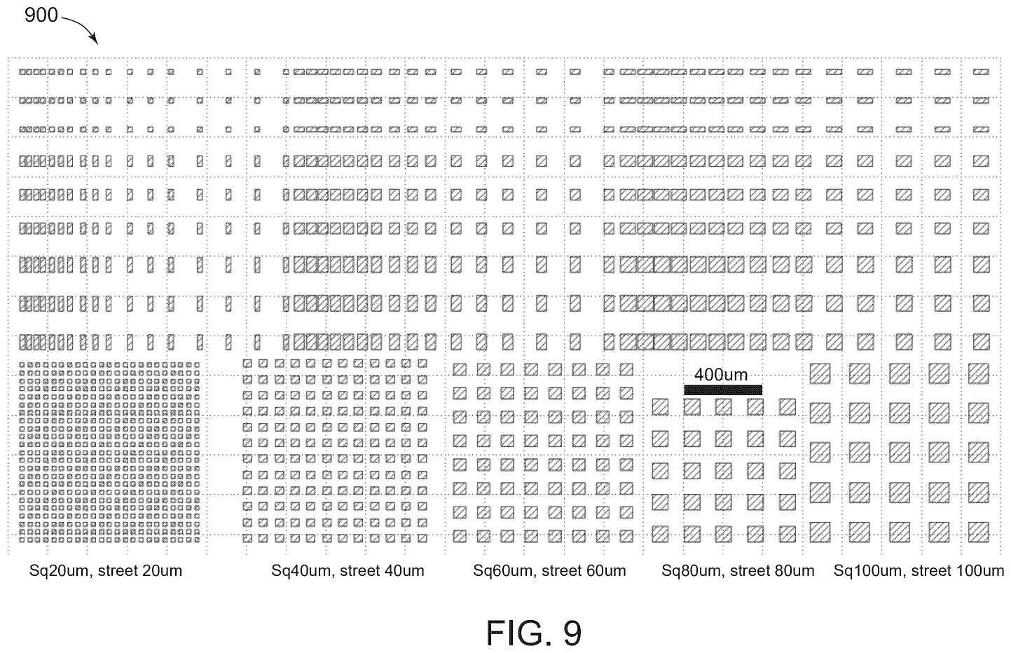

In one embodiment, photolithography or UV lithography is used to fabricate patterned surfaces and structures, such as films. In one embodiment, an ink composition comprising an optically active material (e.g., a phosphor material) and a photoresist material is deposited on a flat or structured surface (e.g., substrate). The ink composition may comprise any of the ink compositions disclosed herein. In one embodiment, the flat or structured surface comprises at least one of a glass, plastic, or flexible material. Next, a photolithographic mask that contains the desired pattern is then placed over the ink composition. In one embodiment the photomask comprises a plurality of openings. Light is shone through the photolithographic mask, exposing the photoresist in the ink composition in certain areas (e.g., the openings in the photolithographic mask). An example photolithographic mask is shown in FIG. 9. The exposed areas undergo a chemical change, making them either soluble or insoluble in a developer solution. In one embodiment the light used is UV light. In this way, a patterned surface comprising a plurality of pattern elements is formed. In one embodiment, the plurality of pattern elements comprise a plurality of discrete regions. In one embodiment, the patterned surface comprises at least one pattern element sized less than or equal to 250 microns. In another embodiment, the patterned surface comprises at least one pattern element sized less than or equal to 100 microns. In another embodiment, the patterned surface comprises at least one pattern element sized less than or equal to 80 microns. In another embodiment, the patterned surface comprises at least one pattern element sized less than or equal to 60 microns. In another embodiment, the patterned surface comprises at least one pattern element sized less than or equal to 40 microns. In another embodiment, the patterned surface comprises at least one pattern element sized less than or equal to 50 microns. In another embodiment, the patterned surface comprises at least one pattern element sized less than or equal to 20 microns. In another embodiment, the patterned surface comprises at least one pattern element sized less than or equal to 10 microns.

In one embodiment, the size of the plurality of pattern elements is associated with a size of the opening of the photolithographic mask used. In one embodiment, the photolithographic mask used comprises at least one opening sized less than or equal to 250 microns. In another embodiment, the photolithographic mask used comprises at least one opening sized less than or equal to 100 microns. In another embodiment, the photolithographic mask used comprises at least one opening sized less than or equal to 80 microns. In another embodiment, the photolithographic mask used comprises at least one opening sized less than or equal to 60 microns. In another embodiment, the photolithographic mask used comprises at least one opening sized less than or equal to 50 microns. In another embodiment, the photolithographic mask used comprises at least one opening sized less than or equal to 40 microns. In another embodiment, the photolithographic mask used comprises at least one opening sized less than or equal to 20 microns. In another embodiment, the photolithographic mask used comprises at least one opening sized less than or equal to 10 microns.

In one embodiment, a plurality of LED light sources are each optically coupled and/or radiationally connected to at least one pattern element of the plurality of pattern elements. In one embodiment, the plurality of LED light sources comprises mini-LEDs. In a further embodiment, at least one pattern element of the plurality of pattern elements are sized less than or equal to 250 microns. In one embodiment, at least one pattern element of the plurality of pattern elements are sized less than or equal to 200 microns. In one embodiment, a D50 particle size of the at least one optically active material is less than the size of the plurality of pattern elements. In a further embodiment, the at least one optically active material has a D50 particle size of less than 20 microns. In one embodiment, the D50 particle size may be from about 0.1 microns to about 20 microns. In another embodiment, the D50 particle size may be from about 0.5 microns to about 20 microns. In another embodiment, the D50 particle size is from about 0.5 microns to about 15 microns. In another embodiment, the D50 particle size is from about 0.5 microns to about 10 microns. In another embodiment, the D50 particle size is from about 0.5 microns to about 5 microns. In another embodiment, the D50 particle size is from about 0.5 microns to about 3 microns. In another embodiment, the plurality of LED light sources comprises micro-LEDs. In a further embodiment, at least one pattern element of the plurality of patterned elements are sized less than or equal to 50 microns.

In another embodiment, the plurality of LED light sources comprises micro-LEDs. In a further embodiment, at least one pattern element of the plurality of pattern elements are sized less than or equal to 50 microns. In one embodiment, a D50 particle size of the at least one optically active material is less than the size of the plurality of pattern elements. In a further embodiment, the at least one optically active material has a D50 particle size of less than 20 microns. In one embodiment, the D50 particle size may be from about 0.1 micron to about 20 microns. In another embodiment, the D50 particle size may be from about 0.5 microns to about 20 microns. In another embodiment, the D50 particle size is from about 0.5 microns to about 15 microns. In another embodiment, the D50 particle size is from about 0.5 microns to about 10 microns. In another embodiment, the D50 particle size is from about 0.5 microns to about 5 microns. In another embodiment, the D50 particle size is from about 0.5 microns to about 3 microns.

In one embodiment, the Mn⁴⁺ doped phosphor may be a manganese-doped potassium fluorosilicate, such as K₂SiF₆:Mn⁴⁺ (PFS). PFS has a narrow band emission having multiple peaks with an average full width at half maximum (FWHM) of less than 4 nm. In another embodiment, the red-emitting phosphor may be Na₂SiF₆:Mn⁴⁺ (NFS).

In one embodiment, Mn⁴⁺ doped phosphors may be further treated, such as by annealing, wash treatment, roasting or any combination of these treatments. Post-treatment processes for Mn⁴⁺ doped phosphors are described in U.S. Pat. Nos. 8,906,724, 8,252,613, 9,698,314, 9,982,190, 11,193,059, and 11,261,375, the entire contents of each of which are incorporated herein by reference. In one embodiment, the Mn⁴⁺ doped phosphors may be annealed, treated with multiple wash treatments and roasted.

To improve reliability, the Mn⁴⁺ doped phosphor of Formula I may be at least partially coated with surface coatings to enhance stability of the phosphor particles and resist aggregation by modifying the surface of the particles and increase the zeta potential of the particles. In one embodiment, the surface coatings may be a metal fluoride, silica or organic coating. In one embodiment, the red-emitting phosphors based on complex fluoride materials activated by Mn⁴⁺ phosphors are at least partially coated with a metal fluoride, which increases positive Zeta potential and reduces agglomeration. In one embodiment, the metal fluoride coating includes MgF₂, CaF₂, SrF₂, BaF₂, AgF, ZnF₂, AlF₃ or a combination thereof. In another embodiment, the metal fluoride coating is in an amount from about 0.1 wt % to about 10 wt %. In another embodiment, the metal fluoride coating is present in an amount from about 0.1 wt % to about 5 wt %. In another embodiment, the metal fluoride coating is present from about 0.3 wt % to about 3 wt %. Metal fluoride coated red-emitting phosphors based on complex fluoride materials activated by Mn⁴⁺ are prepared as described in WO 2018/093832, US Publication No. 2018/0163126 and US Publication No. 2020/0369956, the entire contents of each of which are incorporated herein by reference.

The phosphor material may include additional phosphors, such as an Yttrium Aluminum Garnet phosphor (YAG). The ratio of powders (YAG:PFS) may be tuned to reach a desired color point. The phosphor material may include additional phosphors, such as rare earth Garnet phosphors. The rare earth elements include Sc, Y, La, Ce, Pr, Nd, Pm, Sm, Eu, Gd, Tb, Dy, Ho, Er, Tm, Yb and Lu. In one embodiment, the rare earth Garnet phosphor is an yttrium aluminum garnet phosphor (YAG). The ratio of the rare earth garnet phosphors to Mn⁴⁺ doped phosphor may be tuned to reach a desired color point.

In some embodiments, the phosphor material may be a red-emitting phosphor based on complex fluoride materials activated by Mn⁴⁺.

The phosphor composition may include one or more other luminescent materials. Additional luminescent materials, such as blue, yellow, red, orange, or other color phosphors may be used in the phosphor composition to customize the white color of the resulting light and produce specific spectral power distributions.

Suitable phosphors for use in the phosphor composition, include, but are not limited to: ((Sr_{1-z}[Ca,Ba,Mg,Zn]_{z})_{1-(x+w)}[Li,Na,K,Rb]Ceₓ)₃(Al_{1-y}Si_{y})O_{4+y+3(x-w)}F_{1-y-3(x-w)}, 0<x≤0.10, 0≤y≤0.5, 0≤z≤0.5, 0≤w≤x; [Ca,Ce]₃Sc₂Si₃O₁₂ (CaSiG); [Sr,Ca,Ba]₃Al₁₋ₓSiₓO₄₊ₓF₁₋ₓ:Ce³⁺ (SASOF)); [Ba,Sr,Ca]₅(PO₄)₃[Cl,F,Br,OH]:Eu²⁺,Mn²⁺; [Ba,Sr,Ca]BPO₅:Eu²⁺,Mn²⁺; [Sr,Ca]₁₀(PO₄)₆*vB₂O₃:Eu²⁺ (wherein 0<v≤1); Sr₂Si₃O₈*2SrCl₂:Eu²⁺; [Ca,Sr,Ba]₃MgSi₂O₈:Eu²⁺,Mn²⁺; BaAl₈O₁₃:Eu²⁺; 2SrO*0.84P₂O₅*0.16B₂O₃:Eu²⁺; [Ba,Sr,Ca]MgAl₁₀O₁₇:Eu²⁺,Mn²⁺; [Ba,Sr,Ca]Al₂O₄:Eu²⁺; [Y,Gd,Lu,Sc,La]BO₃:Ce³⁺,Tb³⁺; ZnS:Cu⁺,Cl⁻; ZnS:Cu⁺,Al³⁺; ZnS:Ag⁺,Cl⁻; ZnS:Ag⁺,Al³⁺; [Ba,Sr,Ca]₂Si₁₋ₙO₄₋₂ₙ:Eu²⁺ (wherein 0≤n≤0.2); [Ba,Sr,Ca]₂[Mg,Zn]Si₂O₇:Eu²⁺; [Sr,Ca,Ba][Al,Ga,In]₂S₄:Eu²⁺; [Y,Gd,Tb,La,Sm,Pr,Lu]₃[Al,Ga]₅₋ₐO_{12-3/2a}:Ce³⁺ (wherein 0≤a≤0.5); [Ca,Sr]₈[Mg,Zn](SiO₄)₄Cl₂:Eu²⁺,Mn²⁺; Na₂Gd₂B₂O₇:Ce³⁺,Tb³⁺; [Sr,Ca,Ba,Mg,Zn]₂P₂O₇:Eu²⁺,Mn²⁺; [Gd,Y,Lu,La]₂O₃:Eu³⁺,Bi³⁺; [Gd,Y,Lu,La]₂O₂S:Eu³⁺,Bi³⁺; [Gd,Y,Lu,La]VO₄:Eu³⁺,Bi³⁺; [Ca,Sr,Mg]S:Eu²⁺,Ce³⁺; SrY₂S₄:Eu²⁺; CaLa₂S₄:Ce³⁺; [Ba,Sr,Ca]MgP₂O₇:Eu²⁺,Mn²⁺; [Y,Lu]₂WO₆:Eu³⁺,Mo⁶⁺; [Ba,Sr,Ca]_{b}Si_{g}Nₘ:Eu²⁺ (wherein 2b+4g=3m); Ca₃(SiO₄)Cl₂:Eu²⁺; [Lu,Sc,Y,Tb]₂₋ᵤ₋ᵥCeᵥCa₁₊ᵤLi_{w}Mg_{2-w}P_{w}[Si,Ge]_{3-w}O_{12-u/2} (where 0.5<u<1, 0<v≤0.1, and 0≤w≤0.2); [Y,Lu,Gd]₂₋ₘ[Y,Lu,Gd]CaₘSi₄N₆₊ₘC₁₋ₘ:Ce³⁺, (wherein 0≤m≤0.5); [Lu,Ca,Li,Mg,Y], alpha-SiAlON doped with Eu²⁺ and/or Ce³⁺; Sr(LiAl₃N₄):Eu²⁺, [Ca,Sr,Ba]SiO₂N₂:Eu²⁺,Ce³⁺; beta-SiAlON:Eu²⁺; 3.5MgO*0.5MgF₂*GeO₂:Mn⁴⁺; Ca_{1-c-f}Ce_{c}Eu_{f}Al_{1+c}Si_{1-c}N₃, (where 0≤c≤0.2, 0≤f≤0.2); Ca₁₋ₕ₋ᵣCeₕEuᵣAl₁₋ₕ(Mg,Zn)ₕSiN₃, (where 0≤h≤0.2, 0≤r≤0.2); Ca₁₋₂ₛ₋ₜCeₛ[Li,Na]ₛEuₜAlSiN₃, (where 0≤s≤0.2, 0≤t≤0.2, s+t>0); [Sr, Ca]AlSiN₃; and Eu²⁺, Ce³⁺, Li₂CaSiO₄:Eu²⁺.

In particular embodiments, additional phosphors include: [Y,Gd,Lu,Tb]₃[Al,Ga]₅O₁₂:Ce³⁺, P-SiAlON:Eu²⁺, [Sr,Ca,Ba][Ga,Al]₂S₄:Eu²⁺, [Li,Ca]α-SiAlON:Eu²⁺, [Ba,Sr,Ca]₂Si₅N₈:Eu²⁺, [Ca,Sr]AlSiN₃:Eu²⁺, [Ba,Sr,Ca]LiAl₃N₄:Eu²⁺, [Sr,Ca,Mg]S:Eu²⁺, and [Ba,Sr,Ca]₂Si₂O₄:Eu²⁺.

Other additional luminescent materials suitable for use in the ink composition may include electroluminescent polymers such as polyfluorenes, preferably poly(9,9-dioctyl fluorene) and copolymers thereof, such as poly(9,9′-dioctylfluorene-co-bis-N,N′-(4-butylphenyl)diphenylamine) (F8-TFB); poly(vinylcarbazole) and polyphenylenevinylene and their derivatives. In addition, the light emitting layer may include a blue, yellow, orange, green or red phosphorescent dye or metal complex, a quantum dot material, or a combination thereof. Materials suitable for use as the phosphorescent dye include, but are not limited to, tris(1-phenylisoquinoline) iridium (III) (red dye), tris(2-phenylpyridine) iridium (green dye) and iridium (III) bis(2-(4,6-difluorephenyl)pyridinato-N,C2) (blue dye). Commercially available fluorescent and phosphorescent metal complexes from ADS (American Dyes Source, Inc.) may also be used. ADS green dyes include ADS060GE, ADS061GE, ADS063GE, and ADS066GE, ADS078GE, and ADSO90GE. ADS blue dyes include ADS064BE, ADS065BE, and ADS070BE. ADS red dyes include ADS067RE, ADS068RE, ADS069RE, ADS075RE, ADS076RE, ADS067RE, and ADS077RE.

Exemplary QD materials include, but are not limited to, group II-IV compound semiconductors such as CdS, CdSe, CdS/ZnS, CdSe/ZnS or CdSe/CdS/ZnS, group II-VI, such as CdTe, ZnSe, ZnTe, ZnS, HgTe, HgS, HgSe, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, HgZnSTe, group III-V or group IV-VI compound semiconductors such as GaN, GaP, GaNP, GaNAs, GaPAs, GaAs, GaAlNP, GaAlNAs, GaAlPAs, GaInNP, GaInNAs, GaInPAs, AlN, AlNP, AlNAs, AlP, AlPAs, AlAs, InN, InNP, InP, InNAs, InPAs, InAS, InAlNP, InAlNAs, InAlPAs, PbS/ZnS or PbSe/ZnS, group IV, such as Si, Ge, SiC, and SiGe, chalcopyrite-type compounds, including, but not limited to, CuInS₂, CuInSe₂, CuGaS₂, CuGaSe₂, AgInS₂, AgInSe₂, AgGaS₂, AgGaSe₂ or perovskite QDs having a formula of ABX₃ where A is cesium, methylammonium or formamidinium, B is lead or tin and C is chloride, bromide or iodide. The quantum dot material may include core-shell nanostructures having an Ag—In—Ga—S(AIGS) core and an Ag—Ga—S(AGS) shell.

In one embodiment, the perovskite quantum dot may be CsPbX3, where X is Cl, Br, I or a combination thereof. The mean size of the QD materials may range from about 2 nm to about 20 nm. The surface of QD particles may be further modified with ligands such as amine ligands, phosphine ligands, phosphatide and polyvinylpyridine. In one aspect, the red phosphor may be a quantum dot material.

All of the semiconductor quantum dots may also have appropriate shells or coatings for passivation and/or environmental protection. The QD materials may be a core/shell QD, including a core, at least one shell coated on the core, and an outer coating including one or more ligands, preferably organic polymeric ligands. Exemplary materials for preparing core-shell QDs include, but are not limited to, Si, Ge, Sn, Se, Te, B, C (including diamond), P, Co, Au, BN, BP, BAs, AlN, AlP, AlAs, AlSb, GaN, GaP, GaAs, GaSb, InN, InP, InAs, InSb, AlN, AlP, AlAs, AlSb, GaN, GaP, GaAs, GaSb, ZnO, ZnS, ZnSe, ZnTe, CdS, CdSe, CdSeZn, CdTe, HgS, HgSe, HgTe, BeS, BeSe, BeTe, MgS, MgSe, MnS, MnSe, GeS, GeSe, GeTe, SnS, SnSe, SnTe, PbO, PbS, PbSe, PbTe, CuF, CuCl, CuBr, CuI, Si₃N₄, Ge₃N₄, Al₂O₃, [Al, Ga, In]₂[S, Se, Te]₃, and appropriate combinations of two or more such materials. Exemplary core-shell luminescent nanocrystals include, but are not limited to, CdSe/ZnS, CdSe/CdS, CdSe/CdS/ZnS, CdSeZn/CdS/ZnS, CdSeZn/ZnS, InP/ZnS, PbSe/PbS, PbSe/PbS, CdTe/CdS and CdTe/ZnS.

The ratio of each of the individual phosphors and other luminescent materials in the ink composition may vary depending on the characteristics of the desired light output. The relative proportions of the individual phosphors and other luminescent materials in the various ink compositions may be adjusted such that when their emissions are blended and employed in a device, for example a lighting apparatus, there is produced visible light of predetermined x and y values on the CIE chromaticity diagram.

In one embodiment, films may be prepared from the ink compositions. The films may be deposited on substrates, such as flexible substrates, polymeric substrates, silicon substrates, thermoplastic substrates, and/or glass substrates. Films may be deposited on LEDs, such as mini-LEDs or micro-LEDs, such as by coating, using a doctor's blade or by printing. In one embodiment, a film is prepared by coating the ink composition on a glass substrate with a doctor's blade. The solvent may be removed, and the film is cured, such as by UV light or heat curing.

The phosphor composition may be in the form of an ink or slurry composition, which can be applied to a substrate, such as an LED light source or formed into a film. The ink composition may be blended with a binder and/or a solvent.

The ink composition may include a binder material to further optimize the ink properties. A wide variety of binders and resin systems, with different chemistries and viscosities may be used. The viscosity of the binder material may allow for the incorporation of phosphor particles and the deposition (e.g., film forming) technique of choice.

In one embodiment, the binder matrix includes a crosslinked polymer. In another embodiment, the binder material includes curable materials, such as photocurable or UV-curable materials or thermally curable or thermoset binder materials or a combination. A thermally curable or thermoset binder material will polymerize or crosslink and form a cured resin binder matrix. Exemplary thermoset and UV binder materials include epoxy, acrylate, methacrylate, vinyl ester and siloxane families. Examples of suitable commercial resin systems include, but are not limited to a Pixelligent UVG Curable ink base, Optical Adhesive (Norland 68T), Pixelligent PixJet SFZ-1 with 40 wt % ZrO2 in acrylic formulation.

In one embodiment, the binder materials may include photoresist materials, such as positive photoresist materials and negative photoresist materials. A positive photoresist is a type of photoresist in which the portion of the photoresist exposed to light becomes more soluble to a photoresist developer. The unexposed portion of the photoresist remains insoluble to the photoresist developer. A negative photoresist is a type of photoresist in which the portion of the photoresist exposed to light becomes insoluble to a photoresist developer. The unexposed portion of the photoresist is dissolved by the photoresist developer. Exemplary positive photoresist materials include, but are not limited to, polymethyl methacrylate (PMMA), Megaposit™ SPR™ series, diazonaphthoquinone (DNQ) and novolac resin. Exemplary negative photoresist materials include, but are not limited to, epoxy-based polymers, thiol-ene (OSTE) polymers and crosslinkable monomers, such as allyl monomers. An example of a suitable commercial negative photoresist material is SU8-3000 permanent negative epoxy photoresist manufactured by Kayaku Advanced Materials®.

In one embodiment, the binder materials may include curable precursor materials, such as photocurable or UV-curable precursor materials and thermally curable or thermoset binder precursor materials. Exemplary thermoset binder precursor materials include silicone materials, such as Sylgard™ 184, Sylgard™ 186, Sylgard™ 527 and epoxy-based materials. Photocurable or UV-curable materials may include precursor materials with mono-functional groups, such as isobornyl acrylate, isodecyl acrylate, 2-ethylhexyl acrylate, tetrahydro furfuryl methacrylate, tetrahydro furfuryl acrylate, stearyl acrylate, t-butyl cyclohexyl acrylate, stearyl methacrylate, 2-phenoxyethyl methacrylate, cyclic trimethylolpropane formal acrylate, N-acryloyl morpholine and diacetone acrylamide; bi-functional groups, such as 1,4-butanediol diacrylate, diethylene glycol diacrylate, diethylene glycol dimethacrylate, neopentyl glycol diacrylate, triethylene glycol diacrylate, dipropylene glycol diacrylate, tricyclodecane dimethanol diacrylate and propoxylated (2) neopentyl glycol diacrylate; and multi-functional groups, such as trimethylolpropane triacrylate, tris(2-hydroxy ethyl) isocyanurate triacrylate, pentaerythratol triacrylate, ethoxylated (3) trimethylolpropane triacrylate and propoxylated (6) trimethylolpropane triacrylate. In one embodiment, the precursor materials include pentaacrylate ester, epoxy resins, acrylic resins, acrylate resins and urethane-based materials. In one embodiment, the binder materials may include photo-initiators for curing the photocurable or UV-curable materials.

In one embodiment, the binder material may be present in an amount up to about 75 wt %. In another embodiment, the binder may be present in an amount up to about 70 wt %. In another embodiment, the binder may be present in an amount from about 5 wt % to about 75 wt %. In another embodiment, the binder is present in an amount of from about 10 wt % to about 70 wt %. In another embodiment, the binder is present from about 20 wt % to about 50 wt %. The weight % is based on total weight of the ink composition.

The ink composition may include one or more solvents to further optimize the ink properties. The amount of solvent, solvent polarity, and solvent vapor pressure can aid in making a stable ink that meets viscosity, wettability, and optical density criteria of the ink composition. The solvent may be present in an amount effective for dissolving the phosphor material and/or any binder material and for adjusting the ink composition to a desired viscosity.

In some embodiments, the one or more solvents include a thinner. An example of a suitable commercial thinner comprises SU8-2000 thinner manufactured by Kayaku Advanced Materials®. As noted above, the solvent may be present in an amount effective for adjusting the ink composition to a desired viscosity. In general, more viscous ink compositions will form thicker film, resulting in increased height features. In one embodiment, the solvent may be present from about 5 wt % to 30 wt %. In another embodiment, the solvent may be present from about 10 wt % to about 20 wt %. In another embodiment, the solvent may be present from about 10 wt % to about 16 wt %.

In some embodiments, the phosphor particles can be formulated in inks using several solvent systems with demonstrated utility in the printing industry. Suitable solvents have a boiling point and polarity that match to the desired printing application and do not interact poorly with the binder material or phosphors used.

The solvents may be polar or non-polar. Examples of solvents include, but are not limited to acetone, glycol ethers, such as diethylene glycol methyl ether, propylene methyl acrylates, such as propylene glycol dimethyl acrylate, cyclic aromatic solvents, such as toluene, xylenes and anisol, aliphatic solvents, such as hexane and tetradecane, alcohols, such as ethanol, isopropanol, and octanol, glycols, such as ethylene glycol and propylene glycol, terpineol, acetates, such as butyl acetate, propylene glycol methyl ether acetate (PGMEA), N-methyl pyrrolidone (NMP), dimethyl sulfoxide (DMSO), dimethyl formamide (DMF), diethylene glycol methyl ether (DGME) and 2-(2-Butoxyethoxy)ethyl acetate (BEA).

Co-solvents and mixture of solvents can also be used to improve fluid, printing process and film forming properties. Mixture of solvents can be composed of any two or more of the solvents listed above and can also be comprised of small additions of common organic solvents into one of the solvents above.

Additional additives may be added to the ink composition to further tailor the ink properties or film properties, such as adhesion or cohesion, light scattering, evaporation rate, stability, shelf life, etc.

In one embodiment, the ink composition includes a scattering aid, such as ZrO₂ nanoparticles. Examples of scattering particles include, but are not limited to titanium dioxide (TiO₂), aluminum oxide (Al₂O₃), zirconium oxide (ZrO2), indium tin oxide, cerium oxide, tantalum oxide, zinc oxide (ZnO₂), magnesium fluoride (MgF₂), calcium fluoride (CaF₂), strontium fluoride (SrF₂), barium fluoride (BaF₂), silver fluoride (AgF), aluminum fluoride (AlF₃) or combinations thereof. In other embodiments, additional additives improve film quality, such as Pentaerithritoltetrakis(3-mercaptopropionate) from Bruno Bock (BB PTh).

Additives may be added to the ink composition in an amount of from about 5 wt % to about 20 wt %, based on the weight of the ink composition.

External heating may be used to improve flowability of the ink composition, however, it should be noted that exceeding 65° C. for long periods of time may lead to premature curing. The ink composition may be prepared using a solvent-based mixing and removal approach.

The phosphor and solvent or binder material may be mixed until the phosphor is dispersed in the solvent, and partially removing the solvent. In some embodiments, the solvent is optional. Typically, the base ink, additive and a small amount of the solvent are mixed together and then the phosphor material is added in 2-4 increments with mixing in-between additions. Additional solvent may be needed to achieve the desired viscosity for good dispersion and coating.

When there is more than one phosphor, such as YAG, the second phosphor may be added first, followed by addition of the Mn⁴⁺ phosphor in ˜2 g increments. In one embodiment, the solution is vortexed between each powder addition. For example, the solution may be vortexed for 1 minute after each sample. In another embodiment, the mixture may be horn sonicated.

Once the particles are appropriately dispersed and homogenized, the solvent is partially removed. This process allows for incorporation of a high content of particles and gives the end user control over the viscosity by how much solvent remains in the final formulation.

In one embodiment, the suspension is subject to rotary evaporation until the desired amount of solvent is removed.

The ink solution may be cured after it has been applied in a deposition technique described herein. The ink solution may also be coated onto a substrate or formed into a film. In one embodiment, the ink composition is subject to a suitable temperature for heat curing or to a suitable radiation wavelength for UV curing, such as less than 400 nm.

In one embodiment, a 2-step cure utilizing UV and thermal cure is applied to the ink composition. This system simultaneously contains both photosensitive groups and thermosensitive groups. The first curing process utilizes a UV cure to soft cure the material in place. The wavelength for polymerization initiation is less than 400 nm (to classify as UV cure). The second curing step is a thermal cure, which uses heat to initiate the remainder of the polymerization reaction. The second curing step acts as a binding or through-cure mechanism. In a film, the second step may reduce the volume of the deposited film through shrinkage.

One advantage of the 2-step cure approach for curing a film is that it can tune how much and at what point in the process the deposited film shrinks. Depending on the content of each polymerization initiator, concentration of PFS can be tailored through altering the film densification mechanism. A UV only curing system relies on UV radiation touching every surface and one cannot assume the curing of shadowed or deep areas.

Thermal only cure is not typically fast and therefore “slumping” or segregation/skinning can occur in deposited inks. Using a UV cure to “soft cure” followed by a thermal cure to “through-cure” the shape or film can be envisioned. The 2-step curing approach can also be used to form 1 feature over another cured feature by UV cure, followed by thermal cure to further “bond” the two layers together.

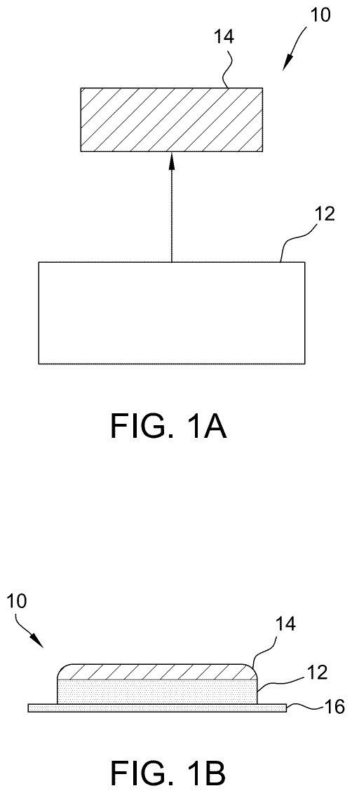

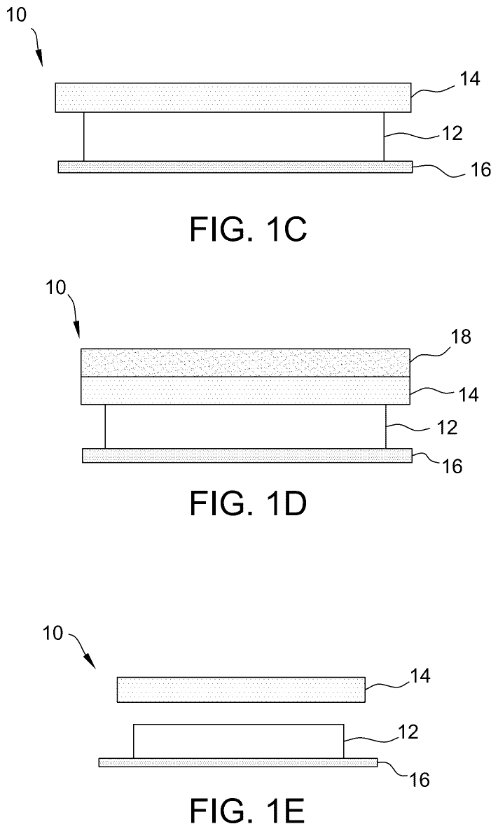

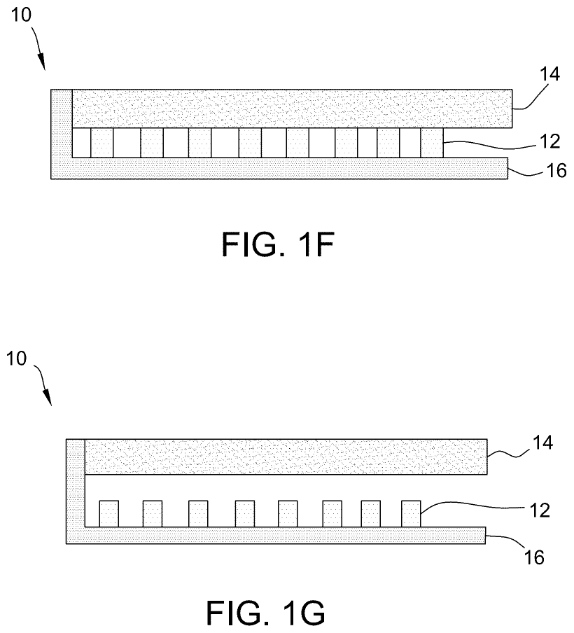

Devices according to the present disclosure include an LED light source radiationally connected and/or optically coupled to the phosphor composition. FIGS. 1A-1G show a device 10, according to various embodiments of the present disclosure. Referring to FIG. 1A, the device 10 includes an LED light source 12 and the phosphor composition 14.

The LED light source 12 may be a UV or blue emitting LED. In some embodiments, the LED light source 12 produces blue light in a wavelength range from about 380 nm to about 460 nm. In the device 10, the phosphor composition 14 is radiationally coupled and/or optically coupled to the LED light source 12. Radiationally connected or coupled or optically coupled means that radiation from the LED light source 12 is able to excite the phosphor composition 14, and the phosphor composition 14 is able to emit light in response to the excitation by the radiation. The phosphor composition 14 may be disposed on a part or portion of the LED light source 12 or located remotely at a distance from the LED light source 12. In some embodiments, the device may be a backlight unit for display applications.

In other embodiments, the LED light source 12 is a micro-LED and the device is for a self-emissive display.

FIG. 1B shows an exemplary embodiment where the phosphor composition 14 depicted as a coating on the LED light source 12. The LED light source 12 is disposed on a reflective layer 16. The reflective layer 16 reflects light from the LED light source 12 toward the LED light source and the phosphor composition 14. The reflective layer 16 may be any material suitable for reflecting light. In one embodiment, the reflective layer 16 may be a metallic layer, such as aluminum, silver, silver alloys or aluminum alloys.

FIG. 1C shows an exemplary embodiment where the phosphor composition 14 is depicted as a layer disposed on the LED light source 12. The LED light source 12 is disposed on the reflective layer 16. The reflective layer 16 reflects light from the LED light source 12 toward the LED light source and the phosphor composition 14. The reflective layer 16 may be any material suitable for reflecting light. In one embodiment, the reflective layer 16 may be a metallic layer, such as aluminum, silver, silver alloys or aluminum alloys.

FIG. 1D shows an exemplary embodiment where the phosphor composition 14 is depicted as a layer disposed on the LED light source 12. An encapsulant or barrier layer 18 is disposed on the phosphor composition 14. The encapsulant or barrier layer 18 may be a low temperature glass, or a polymer or resin known in the art, for example, an epoxy, silicone, epoxy-silicone, acrylate or a combination thereof. The encapsulant or barrier layer 18 should be transparent to allow light to be transmitted through those elements.

FIG. 1E shows an exemplary embodiment where the phosphor composition 14 is depicted as a layer located remotely from the LED light source 12 and the LED light source 12 is disposed on the reflective layer 16.

FIG. 1F shows an exemplary embodiment where the phosphor composition 14 is depicted as a layer disposed on LED light source 12 and the LED light source 12 is depicted as an array of LED light sources. In some embodiments, the LED light sources 12 are mini-LEDs or micro-LEDs. The array of LED light sources 12 is disposed on the reflective layer 16.

FIG. 1G shows an exemplary embodiment where the phosphor composition 14 is depicted as a layer located remotely from the LED light source 12 and LED light source 12 is depicted as an array of LED light sources. In some embodiments, the LED light sources 12 are mini-LEDs or micro-LEDs. The array of LED light sources 12 is disposed on the reflective layer 16.

The general discussion of the example LED light source discussed herein is directed toward an inorganic LED based light source. The most popular white LEDs are based on blue or UV emitting GaInN chips. In addition, to inorganic LED light sources, the term LED light source is meant to encompass all LED light sources, such as semiconductor laser diodes (LD), organic light emitting diodes (OLED) or a hybrid of LED and LD. The LED light source may be a mini-LED or micro-LED, which can be used in self-emissive displays. Further, it should be understood that the LED light source may be replaced, supplemented or augmented by another radiation source unless otherwise noted and that any reference to semiconductor, semiconductor LED, or LED chip is merely representative of any appropriate radiation source, including, but not limited to, LDs and OLEDs.

The phosphor composition 14 may be present in any form such as powder, glass, or composite e.g., phosphor-polymer composite or phosphor-glass composite. Further, the phosphor composition 14 may be used as a layer, sheet, film, strip, dispersed particulates, or a combination thereof. In some embodiments, the phosphor composition 14 includes the phosphor material in glass form. In some of these embodiments, the device 10 may include the phosphor composition 14 in form of a phosphor wheel (not shown). The phosphor wheel may include the phosphor composition embedded in a glass. A phosphor wheel and related devices are described in WO 2017/196779, which is incorporated herein by reference.

The phosphor composition is optically coupled or radiationally connected to an LED light source. In one embodiment, a white light blend may be obtained by the red phosphor material with an LED light source, such as a blue or UV LED.

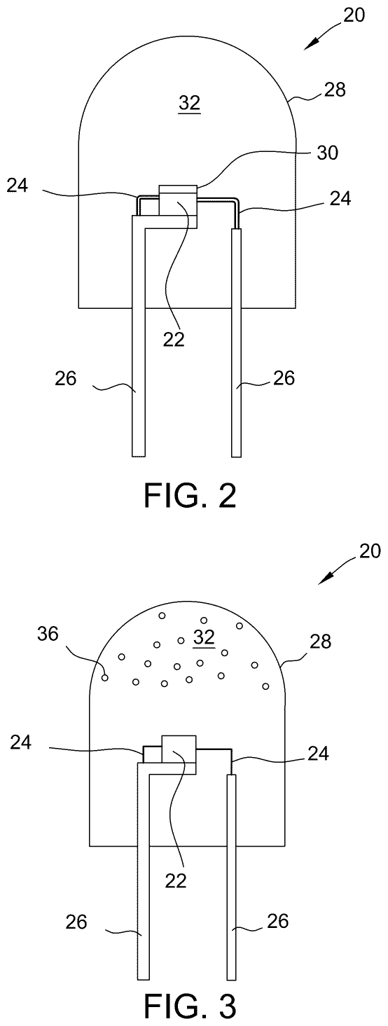

FIG. 2 illustrates a lighting apparatus or lamp 20, in accordance with some embodiments. In one embodiment, the lighting apparatus 20 may be a backlight apparatus. The lighting apparatus 20 includes an LED chip 22 and leads 24 electrically attached to the LED chip 22. The leads 24 may comprise thin wires supported by a thicker lead frame(s) 26 or the leads 24 may comprise self-supported electrodes and the lead frame may be omitted. The leads 24 provide current to LED chip 22 and thus cause it to emit radiation.

A layer 30 of the phosphor composition is disposed on a surface of the LED chip 22. The phosphor layer 30 may be disposed by any appropriate method, for example, using a slurry or ink composition prepared by mixing the phosphor composition and a binder material or solvent (as discussed above). In one such method, a silicone slurry in which the phosphor composition particles are randomly suspended or uniformly dispersed is placed around the LED chip 22. This method is merely exemplary of possible positions of the phosphor layer 30 and LED chip 22. The phosphor layer 30 may be coated over or directly on the light emitting surface of the LED chip 22 by coating and drying the slurry over the LED chip 22. The light emitted by the LED chip 22 mixes with the light emitted by the phosphor composition to produce desired emission.

With continued reference to FIG. 3, the LED chip 22 may be encapsulated within an envelope 28. The envelope 28 may be formed of, for example glass or plastic. The LED chip 22 may be enclosed by an encapsulant material 32. The encapsulant material 32 may be a low temperature glass, or a polymer or resin known in the art, for example, an epoxy, silicone, epoxy-silicone, acrylate or a combination thereof. In an alternative embodiment, the lighting apparatus 20 may only include the encapsulant material 32 without the envelope 28. Both the envelope 28 and the encapsulant material 32 should be transparent to allow light to be transmitted through those elements.

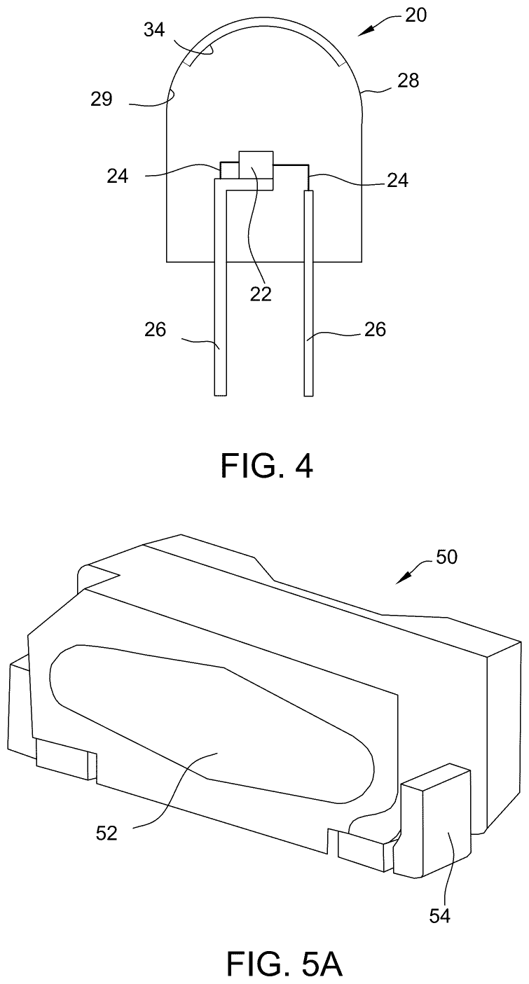

In some embodiments as illustrated in FIG. 3, the phosphor composition 36 is interspersed within the encapsulant material 32, instead of being formed directly on the LED chip 22, as shown in FIG. 4. The phosphor composition 36 may be interspersed within a portion of the encapsulant material 32 or throughout the entire volume of the encapsulant material 32. Blue light or UV light emitted by the LED chip 22 mixes with the light emitted by phosphor composition 36, and the mixed light transmits out from the lighting apparatus 20.

In yet another embodiment, a layer 34 of the phosphor composition is coated onto a surface of the envelope 28, instead of being formed over the LED chip 22, as illustrated in FIG. 4. As shown, the phosphor layer 34 is coated on an inside surface 29 of the envelope 28, although the phosphor layer 34 may be coated on an outside surface of the envelope 28, if desired. The phosphor layer 34 may be coated on the entire surface of the envelope 28 or only a top portion of the inside surface 29 of the envelope 28. The UV/blue light emitted by the LED chip 22 mixes with the light emitted by the phosphor layer 34, and the mixed light transmits out. Of course, the phosphor composition may be located in any two or all three locations (as shown in FIGS. 2-4) or in any other suitable location, such as separately from the envelope 28, remote or integrated into the LED chip 22. In one embodiment, the phosphor layer 34 may be a film and located remotely from the LED chip 22. In another embodiment, the phosphor layer 34 may be a film and disposed on the LED chip 22. In some embodiments, the phosphor layer 34 may be applied to the LED chip 22 as an ink composition. In some embodiments, the phosphor layer 34 may be applied to the LED chip 22 as an ink composition and dried to form a film on the LED chip 22. In some embodiments, the phosphor composition may be a single layer or multi-layered. In some embodiments, the film is a multi-layered structure where each layer of the multi-layered structure includes at least one phosphor or quantum dot material. In another embodiment, a device structure includes a layer of a phosphor composition on an LED chip and a remote layer including a quantum dot material. In another embodiment, a device structure includes a layer of a phosphor composition on an LED chip and a remote layer including a quantum dot material and phosphor material. In another embodiment, a device structure includes a layer of a phosphor composition on an LED chip and a film including quantum dot material located remotely from the LED chip. In another embodiment, a device structure includes a layer of a phosphor composition on an LED chip and a film including quantum dot material and phosphor material located remotely from the LED chip.

In any of the above structures, the lighting apparatus 20 (FIGS. 1-4) may also include a plurality of scattering particles (not shown), which are embedded in the encapsulant material 32. The scattering particles may comprise, for example, alumina, silica, zirconia, or titania. The scattering particles effectively scatter the directional light emitted from the LED chip 22, preferably with a negligible amount of absorption.

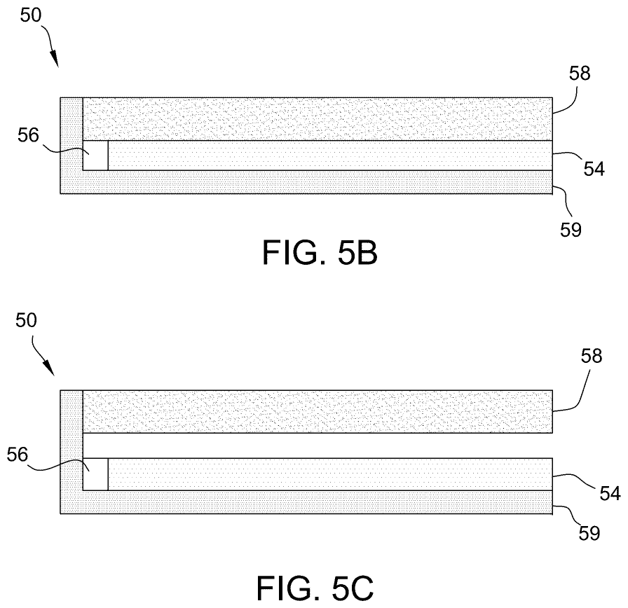

In one embodiment, the lighting apparatus 20 shown in FIG. 3 or FIG. 4 may be a backlight apparatus. In another embodiment, the backlight apparatus comprises a backlight unit 10. Some embodiments include a surface mounted device (SMD) type light emitting diode 50, e.g., as illustrated in FIGS. 5A, 5B and 5C, for backlight applications. Referring to FIG. 5A, SMD is a “side-emitting type” and has a light-emitting window 52 on a protruding portion of a light guiding member 54. An SMD package comprises an LED chip 56 as defined above, and a phosphor composition 58 as described herein. FIG. 5B shows the phosphor composition 58 disposed on the LED chip 56 and FIG. 5C shows the phosphor composition 58 disposed remotely from the LED chip 56. FIGS. 5B and 5C also show the LED chip 56 and the light guiding member 54 disposed on a reflective layer 59. The reflective layer 59 reflects light from the LED chip 56 and the light guiding member 54 toward the phosphor composition 58. The reflective layer 59 may be any material suitable for reflecting light. In one embodiment, the reflective layer 59 may be a metallic layer, such as a silver, aluminum, aluminum alloy or silver alloy. In another embodiment, the device may be a direct lit display.

By use of the phosphor compositions described herein, devices can be provided producing white light for display applications, for example, LCD backlight units, having high color gamut and high luminosity. Alternately, devices can be provided producing white light for general illumination having high luminosity and high CRI values for a wide range of color temperatures of interest (2000 K to 10,000 K).

Devices of the present disclosure include lighting and display apparatuses for general illumination and display applications. Examples of display apparatuses include liquid crystal display (LCD) backlight units, televisions, computer monitors, vehicular displays, laptops, computer notebooks, mobile phones, smartphones, tablet computers and other handheld devices. Where the display is a backlight unit, the phosphor composition may be incorporated in a film, sheet or strip that is radiationally coupled and/or optically coupled to the LED light source, as described in US Patent Application Publication No. 2017/0254943. Examples of other devices include chromatic lamps, plasma screens, xenon excitation lamps, UV excitation marking systems, automotive headlamps, automotive tail-lights, theatre projectors, laser pumped devices, and point sensors. In one embodiment, the device may be a fast response display that does not include an LCD. The fast response display may be a self-emissive display including phosphor converted (PC) micro-LEDs. In some embodiments, the device is a substantially transparent, fully transparent, and/or translucent display. For example, the device may comprise an automotive windshield. In some embodiments, the device comprises a heads-up display (e.g., any transparent display that presents data without requiring users to look away from their usual viewpoints). The heads-up display may comprise an automotive heads-up display, an aircraft heads-up display, a military vehicle heads-up display, an augmented reality (AR) heads-up display, and/or a virtual reality (VR) heads-up display. The list of these applications is meant to be merely exemplary and not exhaustive.

Traditional backlight units use surface-mount device (SMD) LEDs. Traditional SMD LED chips are mounted on a holder and connected to a printed circuit board (PCB) by one or more alloy wires. The electrical current flows from the PCB board and through the alloy wires to power the LED chip. During use, too much heat or a surge in current can damage the alloy wires resulting in LED failure.

As the number of LEDs increase and the optical distance (OD) decreases, it may be preferable to use a chip-scale package (CSP). A CSP is a type of integrated circuit (IC) package that is surface mountable. CSP chips can be directly applied to the PCB effectively shortening the heat flow path to the substrate and reducing the thermal resistance of the light source. Under the same current, CSP chips have higher intensity and lower current consumed compared to SMD LED chips. And since the CSP LED chip has no chip holder or wires connected, two possible LED failure points are removed. Therefore, CSP LEDs features integrated component features that do not need soldered wire connections which reduce thermal resistance, reduce heat transfer path, reduce possible failure points, are smaller in size, have a high optical density, and do not require a substrate.

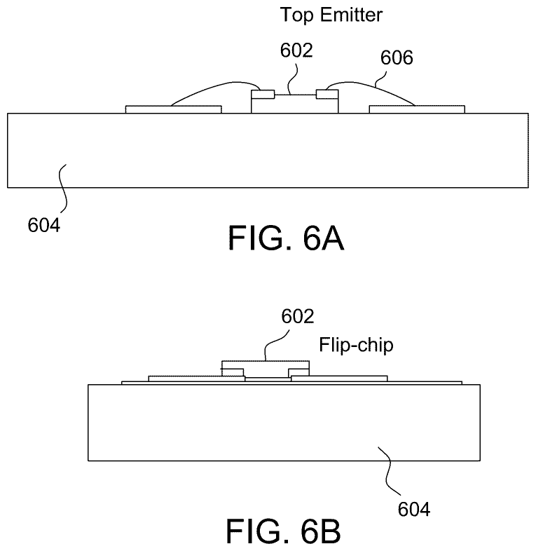

FIG. 6A illustrates a chip-on-board (COB) or chip-on-glass (COG) top emitting device. In the embodiment illustrated in FIG. 6A, an LED chip 602 is mounted on a backlight substrate 604. Backlight substrate 604 may comprise a PCB, a glass circuit board (GCB), or thin-film transistor (TFT) glass. In some embodiments, LED chip 602 is attached to backlight substrate 604 via an adhesive. In the embodiment illustrated in FIG. 6A, LED chip 602 is connected to backlight substrate 604 via one or more wires 606.

FIG. 6B is “flip chip” COB or COG. In flip COB or COG, the LED chip 602 is inverted, with a top layer of metallization facing the backlight substrate 604. Backlight substrate 604 may comprise a PCB, a glass circuit board (GCB), or thin-film transistor (TFT) glass. In some embodiments, small balls of solder are placed on the circuit board traces (not shown) where connections to the chip are required. In some embodiments, LED chip 602 and backlight substrate 604 are passed through a reflow soldering process to make the electrical connections.

CSPs offer advantages like smaller size (reduced footprint and thickness), lesser weight, relatively easier assembly process, lower overall production costs, and improvement in electrical performance. They are also tolerant of chip size changes since a reduced chip size can still be accommodated by the interposer design without changing the CSP's footprint. Further, a CSP LED may have a wider viewing angle of up to 180 degrees because the phosphor is applied on the sides too. This may be very important advantage for applications such as backlight modules, replacement of traditional form factor lamps and tubes.

The CSP product features integrated component features that do not need soldered wire connections which reduce thermal resistance, reduce heat transfer path, and reduce possible failure points. Therefore, in some applications, it may be preferable to use CSPs.

Ink formulations described herein may be implemented in CSPs, such as those illustrated in FIGS. 6A-6B. In some embodiments, such CSPs are used in applications such as LED headlights and various displays. In some embodiments, CSP chips may replicate the size and location of the tungsten filament in halogen bulbs to create beam patterns much like halogen bulbs.

In some embodiments, films including the phosphor composition may be disposed on small-size LEDs, such as micro-LEDs or mini-LEDs. In other embodiments, the film includes phosphors with micron or sub-micron particle sizes. In other embodiments, the film includes nano-sized particles. In one embodiment, the film includes a Mn⁴⁺ doped phosphor having a D50 particle size less than 20 microns, less than 10 m, particularly less than 5 m, more particularly nano-sized. In another embodiment, the D50 particle size may be from about 1 micron to about 20 microns. In another embodiment, the D50 particle size is from about 1 micron to about 15 microns. In another embodiment, the D50 particle size is from about 1 micron to about 10 microns. In another embodiment, the D50 particle size is from about 1 micron to about 5 microns. In another embodiment, the D50 particle size is from about 1 micron to about 3 microns. In another embodiment, the D50 particle size is from about 50 nm to about 1000 nm. In another embodiment, the D50 particle size is from about 100 nm to about 1000 nm. In another embodiment, the D50 particle size is from about 200 nm to about 1000 nm. In another embodiment, the D50 particle size is from about 250 nm to about 1000 nm. In another embodiment, the D50 particle size is from about 500 nm to about 1000 nm. In another embodiment, the D50 particle size is from about 750 nm to about 1000 nm. In another embodiment, the D50 particle size is from about 50 nm to about 10 microns. In another embodiment, the D50 particle size is from about 200 nm to about 5 microns. In another embodiment, the D50 particle size is from about 250 nm to about 5 microns. In another embodiment, the D50 particle size is from about 500 nm to about 5 microns. In another embodiment, the D50 particle size is from about 750 nm to about 5 microns. In another embodiment, the D50 particle size is from about 750 nm to about 3 microns.

In one embodiment, the ink composition may cover at least a portion of an LED, as described in U.S. Pat. No. 11,578,225, the entire contents of which are incorporated herein by reference. In another embodiment, the ink composition may be printed as a pattern on a substrate, such as an LED or glass or silicon substrate or polymeric material, such as a thermoplastic substrate, by ink jet printing. In some embodiments, the ink composition may be placed over a plurality of light sources, such as an array of mini-LEDs or micro-LEDs.

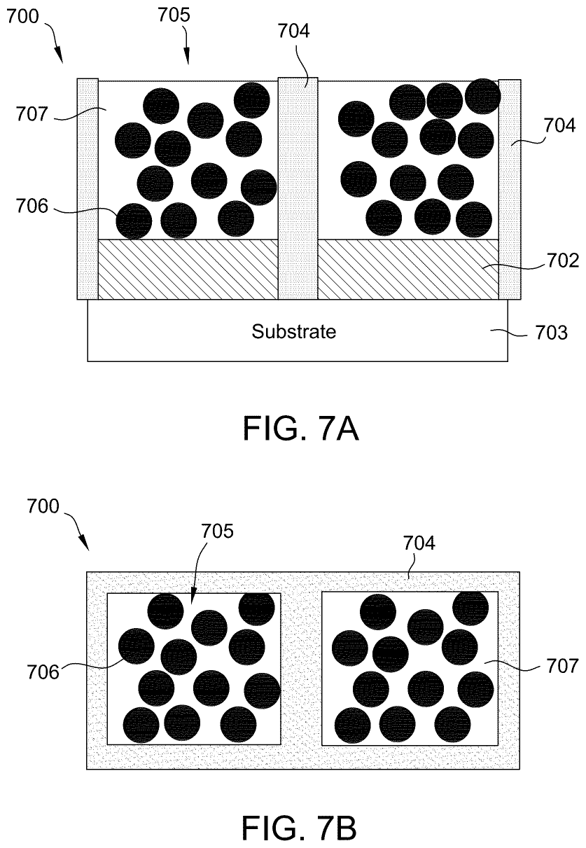

FIGS. 7A and 7B depict a portion of a black matrix 700 according to one embodiment of the present disclosure. A black matrix minimizes cross-talk or optical interference between adjacent pixels and provides good display contrast and definition. The black matrix 700 includes a plurality or an array of light sources 702 disposed on a substrate 703 with each light source 702 spatially separated from other light sources 702 in the array and a non-transmissive region 704 between the spatially separate light sources 702. In one embodiment, the light sources 702 may be separated from about 1 μm to about 1 mm. In another embodiment, the light sources 702 may be separated from about 1 μm to about 500 μm. In another embodiment, the light sources 702 may be separated from about 5 μm to about 300 μm. In another embodiment, the light sources 702 may be separated from about 10 μm to about 200 μm. In another embodiment, the light sources 702 may be separated from about 15 μm to about 30 μm. In one embodiment, the non-transmissive region 704 between the light sources 702 may be from about 1 μm to about 1 mm. In another embodiment, the non-transmissive region 704 between the light sources 702 may be from about 1 μm to about 500 μm. In another embodiment, the non-transmissive region 704 between the light sources 702 may be from about 5 μm to about 300 μm. In another embodiment, the non-transmissive region 704 between the light sources 702 may be from about 10 μm to about 200 μm. In another embodiment, the non-transmissive region 704 between the light sources 702 may be from about 15 μm to about 30 μm.

In one embodiment, a color conversion film, may be deposited on each of the LED light sources by any of the deposition techniques disclosed herein. The LED light sources may comprise mini-LEDs or a micro-LEDs. The color conversion film includes a narrow band emission phosphor dispersed within a matrix. The non-transmissive region 704 is substantially free of the color conversion film 705 and is substantially non-transmissive to light generated from the plurality of light sources 702. The non-transmissive region 704 may be filled by a black matrix material including one or more non-transmissive materials dispersed within a black matrix binder. The non-transmissive materials may include, but are not limited to, carbon black powders, dielectric oxides, such as aluminum oxide, or metal particles, such as Ni, Co, Fe, Cr, Cu, Pd, Au, Pt, Sn, Zn and a combination of such. In one embodiment, the black matrix binder may include binder materials, such as previously described. In another embodiment, the black matrix binder may be silicone materials, thermoplastic polymers or thermoplastic copolymers. In one embodiment, the optical density of the non-transmissive region 704, at the wavelength of light corresponding to the emission spectrum of the narrow band emission phosphor 706, is at least 1.0. In another embodiment, the optical density is at least 2.0. In another embodiment, the optical density is at least 3.0. In one embodiment, the non-transmissive region is black or dark.

The ink composition includes a phosphor material, which may have a D50 particle size in a range from about 0.1 micron to about 20 microns. In another embodiment, the D50 particle size may be from about 0.5 to about 15 microns. The particle sizes need to be small size for preparing ink compositions, for printing and for forming structures, such as films. In another embodiment, the phosphor material includes a D50 particle size in a range from about 0.5 micron to about 10 microns. In another embodiment, the D50 particle size is in a range from about 0.5 micron to about 5 microns. In other embodiments, the phosphor material may have a D50 particle size from about 50 nm to about 1000 nm.

Span of the particle size distribution is not necessarily limited, and may be less than 1.1. In another embodiment, the span of the particle size distribution is <1.0. Span is a measure of the width of the particle size distribution curve for a particulate material or powder, and is defined according to equation:

$$Span = \frac{( {D}_{90} - {D}_{10} )}{{D}_{50}}$$

where D₅₀ is the median particle size for a volume distribution; D₉₀ is the particle size for a volume distribution that is greater than the particle size of 90% of the particles of the distribution; and D₁₀ is the particle size for a volume distribution that is greater than the particle size of 10% of the particles of the distribution.

Quantum efficiency (QE) measurement is known in the art and can be done, for example, with a spectrometer. The Mn⁴⁺ doped phosphor of formula I has a high QE of at least 85%. In another embodiment, the QE is over 90%.

The amount of activator Mn incorporation in the red-emitting phosphors (referred to as Mn %) improves color conversion. Increasing the amount of Mn % incorporation improves color conversion by increasing the intensity of the red emission, maximizing absorption of excitation blue light and reducing the amount of unconverted blue light or bleed-through of blue light from a blue LED.

In one embodiment, the Mn⁴⁺ doped phosphor of formula I has a Mn loading or Mn % of at least 1 wt %. In another embodiment, the phosphor has a Mn loading of at least 1.5 wt %. In another embodiment, the phosphor has a Mn loading of at least 2 wt %. In another embodiment, phosphor has a Mn % of at least 3 wt %. In another embodiment the Mn % is greater than 3.0 wt %. In another embodiment, the content of Mn in the phosphor is from about 1 wt % to about 4 wt %. In another embodiment, the content of Mn in the phosphor is from about 2 wt % to about 4 wt %.

In the following we provide the details of ink formulation, the process used for film formation and development, and the characterization features to show feasibility of phosphor patterning using photolithography tools.

In some embodiments, phosphors are incorporated into a polymer matrix. In some embodiments, the polymer may have one or more of the following properties. First, it may be “photo-definable” using standard tools from the semiconductor and flat panel industries. Second, it may be stable in its operating environment after curing. Third, it may be optically clear when cured. An example polymer with these desired properties is SU-8 resist manufactured by Kayaku Advanced Materials®. Other materials exist which also possess these properties and may be a more suitable matrix, depending on the application. In some embodiments, a layer of the photoresist is created on the application substrate (e.g., a populated LED array). In some embodiments, photolithography methods are used to create optically active structures with the required resolution (e.g., color conversion column on top of the LED array). Using these materials and methods, structures with dimension on the order of 30 microns and smaller may be produced. This is significantly lower than the pixel size attainable by current methods.

### EXAMPLES

### Example Process 1

Applicants note the following processes may be performed under yellow and/or red lights. The process used to form SU8-3025 ink without PFS is as follows: (1) SU8-3025 photoresist and SU8-2000 thinner was added to a 20 ml amber vial; (2) the SU8-3025 photoresist and SU8-2000 thinner was mixed using a vortex mixer on the maximum setting for about 1 minute; (3) the mixture sat for about 5 minutes to release air bubbles; (4) the mixture was dispensed as 1 ml per 1″ of glass wafer diameter; (5) the films were spun at about 0.5 thousand revolutions per minute (krpm) for about 10 seconds and then at about 3.0 krpm for about 60 seconds, or the films were spun at about 0.5 krpm for about 10 seconds and then at about 1.5 krpm for about 60 seconds; (6) the films were soft baked at about 95° C. for about 5 minutes; (7) the films were exposed to UV light for about 10 seconds; (8) post-UV exposure, the films were baked at about 95° C. for about 5 minutes; and (9) the films were partially removed by mechanical means to reveal the substrate and film thickness was measured using Dektak® profilometry.

### Example Process 2

The process used to form SU8-3025 ink with PFS is as follows: (1) SU8-3025 photoresist, SU8-2000 thinner, and PFS % were added to a vial; (2) the components were mixed using a vortex mixer on the maximum setting for about 1 minute; (3) the mixture was left on planetary shaker at about 200 rpm until ready for clean room; (4) the mixing was repeated using a vortex mixer on the maximum setting for about 1 minute; (5) the mixture was passed to the clean room; (6) the films were spun within 1 hour and more particularly, the films were spun at about 0.5 thousand revolutions per minute (krpm) for about 10 seconds and then at about 3.0 krpm for about 60 seconds, or the films were spun at about 0.5 krpm for about 10 seconds and then at about 1.5 krpm for about 60 seconds; (7) the films were exposed to MA6 mask aligner for about 8 seconds; (8) a post-exposure bake was provided at 65° C. for 1 minute and then another post-exposure bake was provided at 95° C. for 5 minutes; (9) the films were cooled; (10) Films were developed with 1-methoxy-2-propanol acetate, films targeting 11 μm thickness developed for 3 min, films targeting 20 μm thickness, developed for 4 min; (11) the films were rinsed with isopropyl alcohol; (12) the films were inspected.

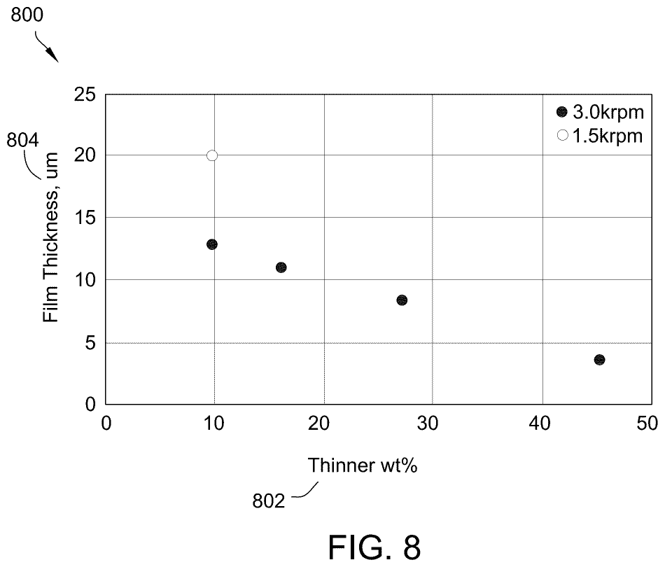

FIG. 8 is a graph 800 showing the correlation of film thickness (microns) on y-axis 804 to thinner by wt % on x-axis 802. Graph 800 illustrates the greater the thinner by wt %, the thinner the film. Graph 800 also illustrates the effect of coating at 1.5 krpm vs 3.0 krpm. For compositions comprising 10 wt % thinner, coating at 3.0 krpm resulted in films having a thickness of about 11 microns, while the same composition spun at 1.5 krpm resulted in films having thickness of about 20 microns.

Sample inks 1-6 were produced using the processes described above. The characteristics of each of sample inks 1-6 are described in Table 1.

TABLE 1
Composition of formed inks
Ink #

| Target film thickness | No PFS | 5% PFS | 15% PFS |
|---|---|---|---|
| 11 microns | 1 | 3 | 5 |
| 20 microns | 2 | 4 | 6 |

Sample inks 1 and 2 were produced using Example Process 1. Sample ink 1 was produced by spinning at 3.0 krpm during step 5 of Example Process 1. Sample ink 1 comprised no PFS and resulted in a film thickness of about 11 microns. Sample ink 2 was produced by spinning at 1.5 krpm during step 5 of Example Process 1. Sample ink 2 also comprised no PFS and resulted in a film thickness of about 20 microns.

Sample inks 3-6 were produced using Example Process 2. Sample inks 3 and 5 were produced by spinning at 3.0 krpm during step 6 of Example Process 2. Sample inks 4 and 6 were produced by spinning at 1.5 krpm during step 6 of Example Process 2. Sample ink 3 comprised about 5% of PFS by weight and resulted in a film thickness of about 11 microns. Sample ink 4 comprised about of 5% PFS by weight and resulted in a film thickness of about 20 microns. Sample ink 5 comprised about 15% of PFS by weight and resulted in a film thickness of about 11 microns. Sample ink 6 comprised about 15% of PFS by weight and resulted in a film thickness of about 20 microns.

To prepare the sample inks, 5 wt % and 15 wt % of PFS would be added to the base composition. In some embodiments, the PFS has a QE over 90%.

FIG. 9 is a schematic diagram of a photolithographic mask design 900. The photolithographic mask 900 was configured in view of resolution pattern. For example, the photolithographic mask pattern shown in FIG. 9 can be used to check if a particular ink formulation can be used to create features down to 20 micron in size and down to 10 micron apart, progressively increasing feature size and distance between them.

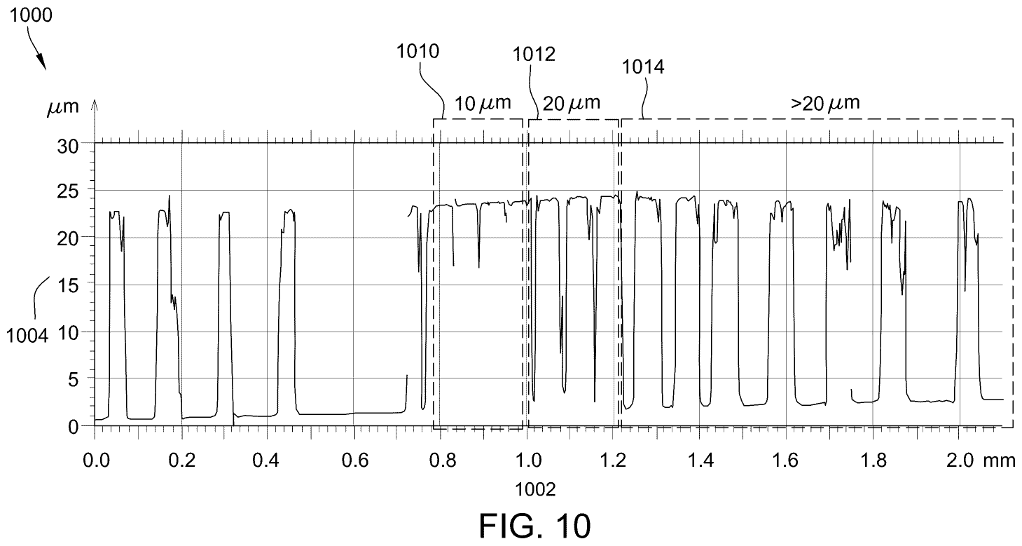

FIG. 10 is a graph 1000 showing the profilometric characterization of the features after completion of the process. More particularly, FIG. 10 is a graph 1000 showing height profile of series of features with progressively increasing distance between features. Section 1010 shows the height profile of the features, created using deposited sample ink 6, designed to be spaced 10 microns apart. Section 1010 demonstrates some clearing between the features, designed to be spaced 10 microns apart, however the clearing between the features is not complete (i.e., the height profile does not reach the substrate level between the features). Section 1012 shows the height profile of the features, created with deposited sample ink 6, designed to be spaced 20 microns apart. Section 1012 demonstrates practically complete clearing between the features designed to be spaced 20 microns apart. Section 1014 shows the height profile of the features, created with ink 6, designed to be spaced more than 20 microns apart. Section 1014 demonstrates well-defined clearings between the features designed to be spaced more than 20 microns apart.

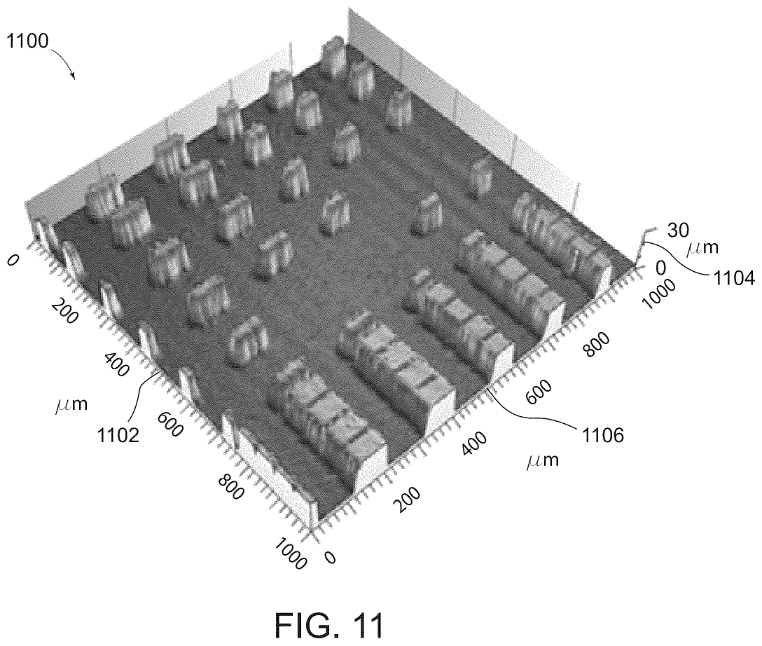

FIG. 11 is a three-dimensional graph 1100 showing the height of the deposited sample ink 6 (microns) 1104, along a length 1106 and width 1102 of the substrate 1102. FIG. 11 further demonstrates some clearing between depositions of sample ink 6 designed to be spaced 10 microns apart, practically complete clearing between depositions of sample ink 6 designed to be spaced 20 microns apart, and well-defined clearings between depositions of sample ink 6.

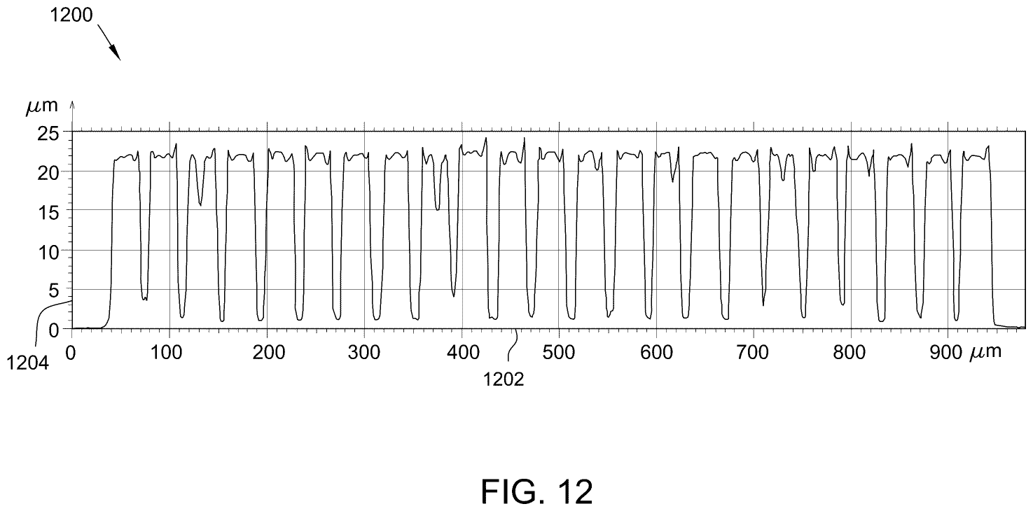

FIG. 12 is another graph showing the profilometric characterization of the features after completion of the process. More particularly, FIG. 12 is a graph 1200 showing the height profile of series of features, where the features are designed to each be 20 microns wide and spaced 20 microns apart. Graph 1200 shows defined gaps between the features that are actually 30 microns wide and spaced 10 microns apart.

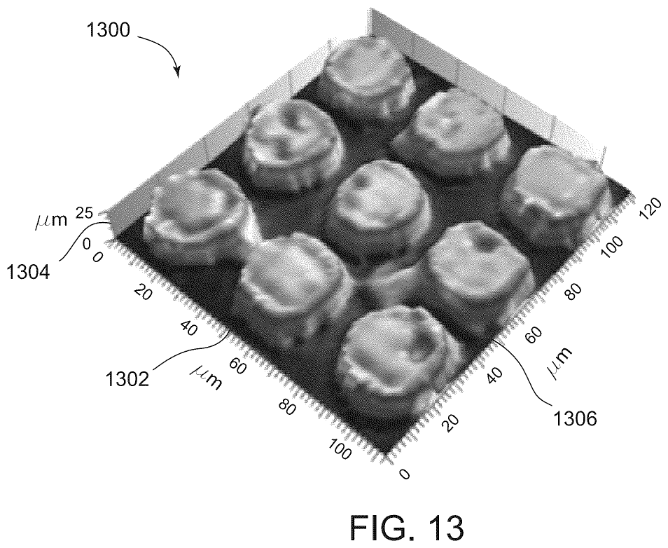

FIG. 13 is a three-dimensional graph 1300 showing the height of the deposited sample ink 6 (microns) along a length 1306 and width 1302 of depositions of sample ink 6 on the substrate designed to be spaced 20 microns apart. FIG. 13 further illustrates well-defined gaps between the depositions of sample ink 6 designed to be spaced 20 microns apart.

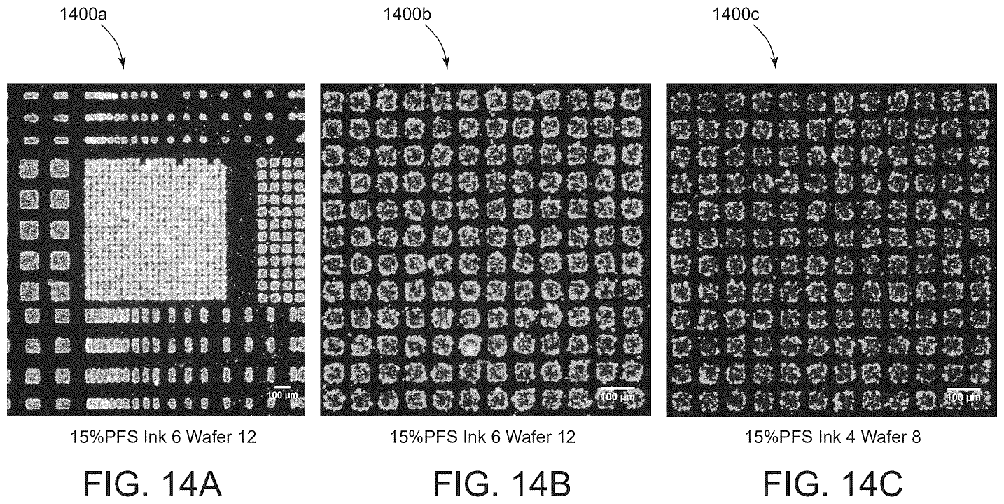

FIGS. 14A-14C comprise UV-microscopy images of ink depositions using photolithographic mask design 900 (shown in FIG. 9). More particularly, FIG. 14A illustrates UV-microscopy image 1400A of depositions of sample ink 6 designed to be 10 microns apart, 20 microns apart, and more than 20 microns apart. FIG. 14B illustrates UV-microscopy image 1400B of depositions of sample ink 6 designed to be 40 microns apart.

FIG. 14C illustrates UV-microscopy image 1400C of depositions of sample ink 4 designed to be 40 microns apart. The UV-microscopy image of FIGS. 14A-14C comprise minimal extraneous red depositions, thereby demonstrating the accuracy and precision of depositing sample inks 4 and 6 using a photolithographic mask design, such as photolithographic mask design 900 (shown in FIG. 9). FIG. 13C further demonstrates that more PFS tends to get to the surface of sample ink 4 as compared to sample ink 6 which has a higher PFS loading.

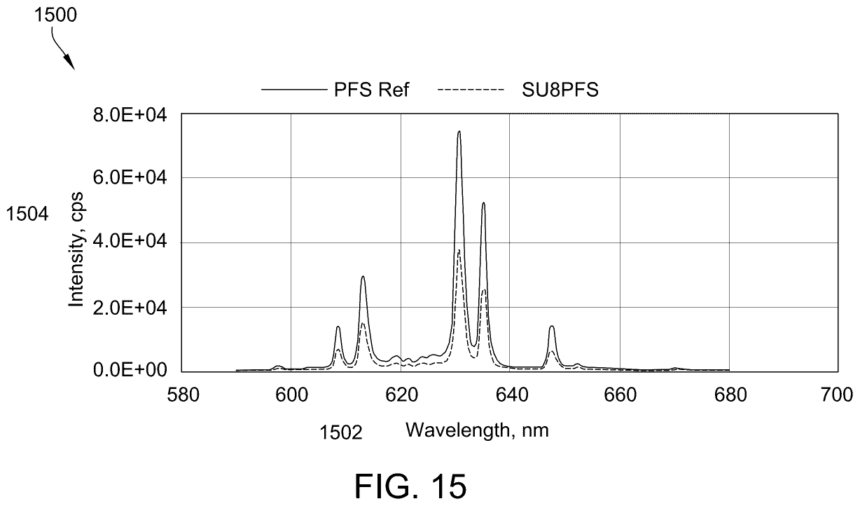

FIG. 15 is a graph 1500 showing the correlation of intensity in counts per second (CPS) on y-axis 1504 to the wavelength (nm) on x-axis 1502. Graph 1500 shows the emission spectrum of the patterned wafer is identical to PFS reference part, and photoluminescence decay time is 8.2 ms, which is close to the PFS reference part. These results demonstrate that no detectable degradation of the photoluminescence properties of the phosphor material occurs as a result of the processing.

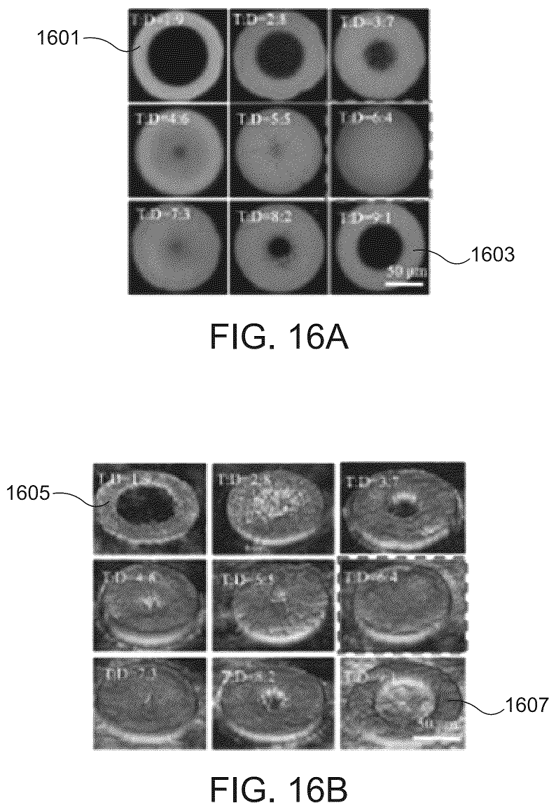

FIG. 16A is a photoluminescence photograph 1600 of a color conversion layer (CCL) pixel. FIG. 16B is a 3D laser confocal microscope photograph of a CCL pixel. CCLs prepared by ink jet printing may be thin, insufficiently absorb ultraviolet/blue light, and have poor surface morphology uniformity. In some embodiments, poor surface morphology uniformity is caused by an intrinsic ring effect, known as the “coffee ring” effect, during the inkjet printing, shown in boxes 1601, 1603, 1605, 1607 of FIGS. 16A and 16B, and as described in “Universal Strategy to Improve the Morphology of the Inkjet Printing Perovskite for Color Conversion Display” by Migchao Zhu et al. (Proceedings of the International Display Workshops, Vol. 30, 2023), which is hereby incorporated by reference as if set forth in its entirety.

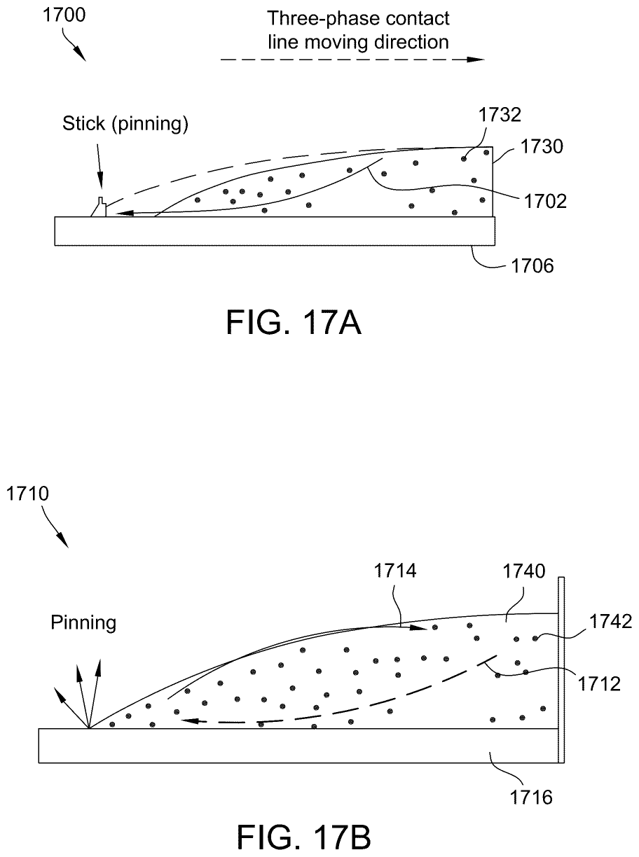

FIG. 17A is a diagram 1700 showing an evaporation rate distribution of an ink composition 1730 comprising a phosphor material 1732 and at least one solvent deposited onto a surface 1706 via ink jet printing. After ink composition 1730 is deposited via inkjet printing, as the at least one solvent beings to evaporate, the evaporation rate at the edge will be higher than that at the center, and as a result, a capillary flow 1702 is formed. Capillary flow 1702 carries the solute from the center to the edge, as indicated by arrow 1702 in FIG. 17A. At this time, if the three-phase contact line is in pinning, the solute will accumulate at the edge and a coffee ring is formed (e.g., box 1601 shown in FIG. 16A).

FIG. 17B is a diagram 1710 showing an evaporation rate distribution of an ink composition 1740 comprising a phosphor material 1742 and at least one solvent deposited onto a surface 1716. Ink composition 1740 of FIG. 17B has a different surface tension distribution than ink composition 1730 of FIG. 17A. When the distribution of surface tension is changed, a Marangoni flow 1714 may be formed, and particles of the ink composition may move from a low surface tension region to a high surface tension region. Therefore, if there is a Marangoni flow 1714 which is opposite to capillary flow 1712 and stronger than capillary flow 1712, the coffee ring can be eliminated, as shown in FIG. 17B.

The ink composition may be any of the ink compositions described herein. In some embodiments, the ink composition includes a phosphor material. For example, in one embodiment, the ink composition includes a KSF phosphor (K₂SiF₆:Mn) with small particle size and high manganese content. As opposed to quantum dot color filter solutions, KSF phosphor (K₂SiF₆:Mn) has a narrower emission intensity, does not have self-absorption issues in thick films, and does not decrease in quantum efficiency when cured into a color filter part. In further embodiments, the KSF phosphor has a D50 particle size from about 0.1 μm to about 15 μm and comprises a Mn content of at least 2.0 wt %. In further embodiments, the KSF phosphor has a D50 particle size from about 0.1 μm to about 8 μm and comprises a Mn content of at least 2.0 wt %. In further embodiments, the KSF phosphor has a D50 particle size from about 0.1 μm to about 4 μm and comprises a Mn content of 2.0-4.0 wt %. In other embodiments, the ink composition includes an NSF phosphor (Na₂SiF₆) with small particle size and high manganese content. The ink composition may be cured using hot air, UV light, and/or any other method known in the art.

In some embodiments, the at least one solvent comprises a solvent mixture of two or more solvents. The resulting “solvent cocktail” produces more homogeneous, uniformly distributed phosphor material in the resulting structure. For example, in some embodiments, the at least one solvent comprises a first solvent and a second solvent. The first solvent has a lower boiling point than the second solvent. Further, the first solvent has a higher surface tension than the second solvent. In some embodiments, the at least one solvent comprises one or more of: gamma-butyrolactone, cyclopentanone, propylene glycol methylether acetate, methylethyl ketone, acetone, benzene, 1-methyl-2-pyrolidone, toluene, (tetrahydro-2-furanyl)methyl ester, diethylene glycol monomethyl ether, acetic acid, acetic anhydride, acetonitrile, benzonitrile, 1-butanol, 2-butanone (or methyl ethyl ketone), butyl acetate, tert-butyl methyl ether, carbon disulfide, carbon tetrachloride, chlorobenzene, 1-chlorobutane (or butyl chloride), chloroform, cyclohexane, cyclopentane, 1,2-dichlorobenzene, 1,2-dichloroethane, dichloromethane, di(ethylene glycol) diethyl ether (or 2-ethoxyethyl ether), N,N-dimethylacetamide, N,N-dimethylformamide, 1,4-dioxane, ether, ethyl acetate, ethyl alcohol, ethylene glycol dimethyl ether (or monoglyme), heptane, hexane, hexanes, 2-methoxyethanol, 2-methoxyethyl acetate, methyl alcohol, 2-methylbutane, 3-methyl-1-butanol (or isoamyl alcohol), 4-methyl-2-pentanone (or methyl isobutyl ketone), 2-methyl-I-propanol (or isobutyl alcohol), 2-methyl-2-propanol, 1-methyl-2-pyrrolidinone, methyl sulfoxide, nitromethane, 1-octanol, pentane, 3-pentanone, 1-propanol, 2-propanol, propylene carbonate, pyridine, tetrachloroethylene, tetrahydrofuran, 1,1,2-trichlorotrifluoroethane, 2,2,4-trimethylpentane, water, m-xylene, o-xylene, and/or p-xylene.

In some embodiments, the ink composition further comprises a binder. The binder may comprise a photoresist (e.g., SU8-3000 permanent negative epoxy photoresist manufactured by Kayaku Advanced Materials®). In further embodiments, the at least one solvent is compatible with the photoresist. For example, in some embodiments, the at least one solvent comprises one or more of gamma-butyrolactone, propylene glycol methylether acetate, methylethyl ketone, acetone, benzene, 1-methyl-2-pyrolidone, toluene, (tetrahydro-2-furanyl)methyl ester, diethylene glycol monomethyl ether.

In some embodiments a temperature and/or a humidity during deposition of an ink composition may affect the distribution of the ink composition on a surface. More particularly, a capillary flow may increase with an increase in temperature and/or decrease in humidity. In some embodiments, a temperature of about 10° C. to 30° C. and a humidity of about 20% to about 40% resulted in a lower capillary flow, thereby minimizing or eliminating the coffee ring effect. More particularly, in some embodiments, a temperature of about 20° C. and a humidity of about 30% eliminated the coffee ring effect.

In some embodiments, a surface on which the ink composition is deposited may affect a thickness of the ink composition. For example, the following substrates resulted in different contact angles and therefore thicknesses for the same ink composition: glass, indium tin oxide (ITO), and poly dimethylsiloxane (PDMS). Therefore, the surface on which an ink composition is deposited may be selected based on the contact angle and/or thickness of the ink composition after deposition.

In some embodiments, a number of drops of ink composition onto a surface may affect a distribution of the ink composition. For example, in some embodiments, a plurality of drops of ink composition on a surface reduce or eliminate the coffee ring effect, as compared to one drop of ink composition. For example, in some embodiments, three drops, four drops, five drops, or six drops of ink composition significantly reduce or eliminate the coffee ring effect.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A device comprising a patterned surface wherein the patterned surface comprises a plurality of pattern elements, a plurality of LED light sources each optically coupled and/or radiationally connected to at least one pattern element of the plurality of pattern elements, wherein the plurality of pattern elements comprise at least one optically active material and a photoresist material.

2. The device according to claim 1, wherein the patterned surface comprises a patterned film.

3. The device according to claim 1, wherein at least one pattern element of the plurality of patterned elements are sized less than or equal to 250 microns.

4. The device according to claim 3, wherein the at least one optically active material has a D50 particle size from about 0.5 microns to about 20 microns.

5. The device according to claim 3, wherein the plurality of LED light sources comprise mini-LEDs.

6. The device according to claim 1, wherein at least one pattern element of the plurality of patterned elements are sized less than or equal to 50 microns.

7. The device according to claim 6, wherein the at least one optically active material has a D50 particle size from about 0.5 microns to about 3 microns.

8. The device according to claim 6, wherein the plurality of LED light sources comprise micro-LEDs.

9. The device according to claim 1, wherein each of the plurality of LED light sources comprise a UV emitting LED or a blue emitting LED.

10. A patterned film comprising at least one optically active material and a photoresist material, the patterned film comprising a plurality of film elements sized less than or equal to 250 microns.

11. The patterned film according to claim 10, wherein the at least one optically active material has a D50 particle size from about 0.5 microns to about 20 microns.

12. The patterned film according to claim 10, wherein the plurality of film elements are sized less than or equal to 50 microns.

13. The patterned film according to claim 12, wherein the at least one optically active material has a D50 particle size from about 0.5 microns to about 3 microns.

14. The patterned film according to claim 10, wherein the at least one optically active material comprises at least one of a phosphor material, a luminescent material, or a scattering aid.

15. The patterned film according to claim 14, wherein the at least one optically active material comprises a phosphor material, the phosphor material comprising a Mn⁴⁺ doped phosphor of formula 1,
$${A}_{x} [ {M F}_{y} ] : {Mn}^{4 +} \qquad I$$
where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

16. The patterned film according to claim 15, wherein the Mn⁴⁺ phosphor of formula I is K₂SiF₆:Mn⁴⁺ or Na₂[SiF₆]:Mn⁴⁺.

17. A method comprising depositing a composition onto a substrate comprising a plurality of light sources, wherein the composition comprises at least one optically active material and a photoresist material, and exposing at least one portion of the composition to light to create a patterned film comprising a plurality of film elements sized less than or equal to 250 microns.

18. The method according to claim 17, wherein the light is ultraviolet (UV) light.

19. The method according to claim 17, further comprising placing a photolithographic mask over the composition before exposing the at least one portion of the composition to light.

20. The method according to claim 17, wherein the at least one optically active material has a D50 particle size from about 0.5 microns to about 20 microns.

21. The method according to claim 20, wherein the patterned film comprises a plurality of film elements sized less than or equal to 50 microns.

22. The method according to claim 17, wherein the at least one optically active material has a D50 particle size from about 0.5 microns to about 3 microns.

23. The method according to claim 17, wherein the at least one optically active material comprises at least one of a phosphor material, a luminescent material, or a scattering aid.

24. The method according to claim 17, wherein the at least one optically active material comprises a phosphor material, the phosphor material comprising a Mn⁴⁺ doped phosphor of formula 1,
$${A}_{x} [ {M F}_{y} ] : {Mn}^{4 +} \qquad I$$
where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

25. The method according to claim 24, wherein the Mn⁴⁺ phosphor of formula I is K₂SiF₆:Mn⁴⁺ or Na₂[SiF₆]:Mn⁴⁺.

26. An ink composition comprising a phosphor material comprising a Mn⁴⁺ doped phosphor of formula 1, at least one binder material, at least one first solvent, and a least one second solvent, wherein the Mn⁴⁺ doped phosphor has a D50 particle size from about 0.5 microns to about 15 microns,
$${A}_{x} [ {M F}_{y} ] : {Mn}^{4 +} \qquad I$$
where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7,
where the at least one first solvent comprises a first boiling point and a first surface tension,
where the at least one second solvent comprises a second boiling point and a second surface tension, and
where the first boiling point is less than the second boiling point and the first surface tension is higher than the second surface tension.

27. The ink composition according to claim 26, wherein the at least one binder material comprises a negative photoresist material.

28. The ink composition according to claim 26, wherein the at least one first solvent and the at least one second solvent are each selected from the group consisting of: gamma-butyrolactone, propylene glycol methylether acetate, methylethyl ketone, acetone, benzene, 1-methyl-2-pyrolidone, toluene, (tetrahydro-2-furanyl)methyl ester, diethylene glycol monomethyl ether.

29. The ink composition according to claim 26, wherein the phosphor material is present in an amount from about 5 wt % to about 20 wt %, based on the weight of the ink composition.

30. The ink composition according to claim 26, wherein the Mn⁴⁺ phosphor of formula I is K₂SiF₆:Mn⁴⁺ or Naz[SiF₆]:Mn⁴⁺.
